(19) United States
(12) Patent Application Publication
(10) Pub. No.: US 2026/0117628 A1
(43) Pub. Date: Apr. 30, 2026

(54) DOWNHOLE TOOL EMPLOYING A FLOW BASED GENERATOR TO INCREASE OR DECREASE A RATE OF REACTION OF A HYDROLYSIS OF AN EXPANDABLE METAL

(71) Applicant: Halliburton Energy Services, Inc., Houston, TX (US)

(72) Inventors: Nithin Kumar Gupta Dachepally, Singapore (SG); Rahul Muruganandam, Singapore (SG); Seng Han Yip, Singapore (SG); Cem Sonat, Singapore (SG); Jalpan Piyush Dave, Singapore (SG); Shanu Thottungal Eldho, Singapore (SG)

(21) Appl. No.: 19/200,075

(22) Filed: May 6, 2025

Related U.S. Application Data
(60) Provisional application No. 63/714,300, filed on Oct. 31, 2024.
(60) Provisional application No. 63/714,341, filed on Oct. 31, 2024.

(51) Int. Cl. E21B 41/00; E21B 33/12

(52) U.S. Cl. CPC E21B 41/0085; E21B 33/1208

(57) ABSTRACT

Energy harvesting devices can be deployed in a wellbore to transform external energy in the wellbore to electric power for consumption by electric devices disposed in the wellbore. A method includes deploying an energy harvesting device downhole in a wellbore, transforming, with the energy harvesting device, external energy in the wellbore to electric power and supplying the electric power from the energy harvesting device to an electric device disposed in the wellbore.

### CROSS-REFERENCE TO RELATED APPLICATION

This application claims the benefit of U.S. Provisional Application Ser. No. 63/714,300, filed on Oct. 31, 2024, entitled “DOWNHOLE TOOL EMPLOYING A THERMOELECTRIC GENERATOR TO INCREASE OR DECREASE A RATE OF REACTION OF A HYDROLYSIS OF AN EXPANDABLE METAL,” and of U.S. Provisional Application Ser. No. 63/714,341, filed on Oct. 31, 2024, entitled “DOWNHOLE TOOL EMPLOYING A THERMOELECTRIC GENERATOR TO INCREASE OR DECREASE A RATE OF REACTION OF A HYDROLYSIS OF AN EXPANDABLE METAL”, both of which are commonly assigned with this application and incorporated herein by reference in their entirety.

### BACKGROUND

Wellbores are drilled into the earth for a variety of purposes including accessing hydrocarbon bearing formations. A variety of downhole tools may be used within a wellbore in connection with accessing and extracting such hydrocarbons. Throughout the process, it may become necessary to isolate sections of the wellbore in order to create pressure zones. Downhole tools, such as frac plugs, bridge plugs, packers, and other suitable tools, may be used to isolate wellbore sections.

The aforementioned downhole tools are commonly run into the wellbore on a conveyance, such as a wireline, work string or production tubing. Such tools often have either an internal or external setting tool, which is used to set the downhole tool within the wellbore and hold the tool in place, and thus function as a wellbore anchor. The wellbore anchors typically include a plurality of slips, which extend outwards when actuated to engage and grip a casing within a wellbore or the open hole itself, and a scaling assembly, which can be made of rubber and extends outwards to seal off the flow of liquid around the downhole tool.

### BRIEF DESCRIPTION

Reference is now made to the following descriptions taken in conjunction with the accompanying drawings, in which:

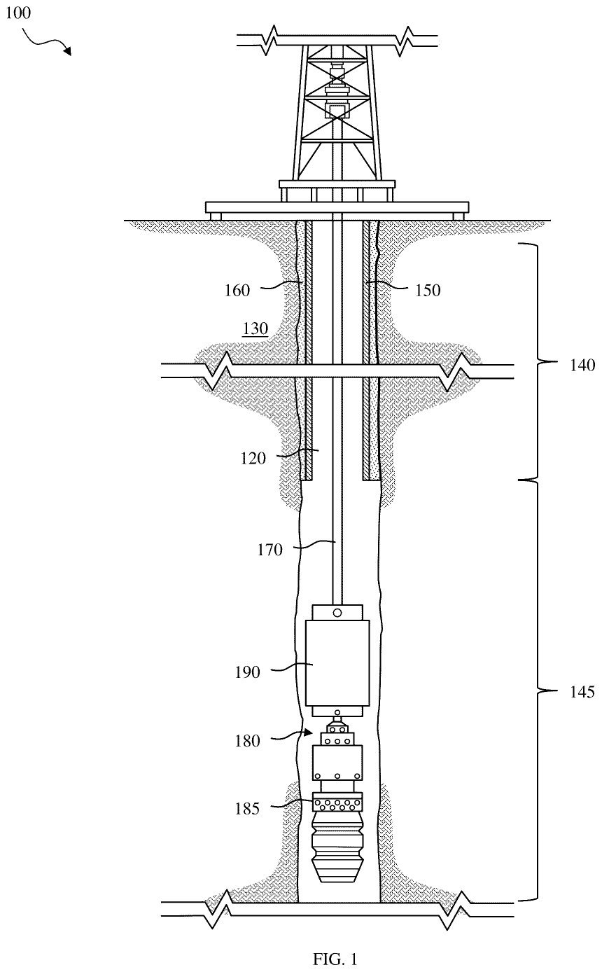

FIG. 1 illustrates a perspective view of a well system including an exemplary operating environment that the devices/apparatuses, systems and methods disclosed herein may be employed;

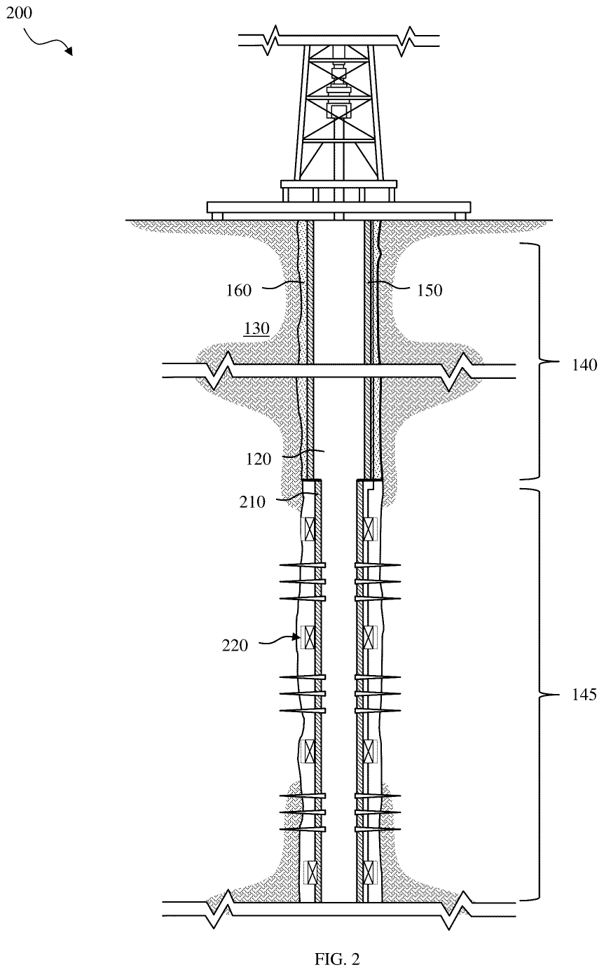

FIG. 2 illustrates a perspective view of an alternative embodiment of a well system including an exemplary operating environment that the apparatuses, systems and methods disclosed herein may be employed;

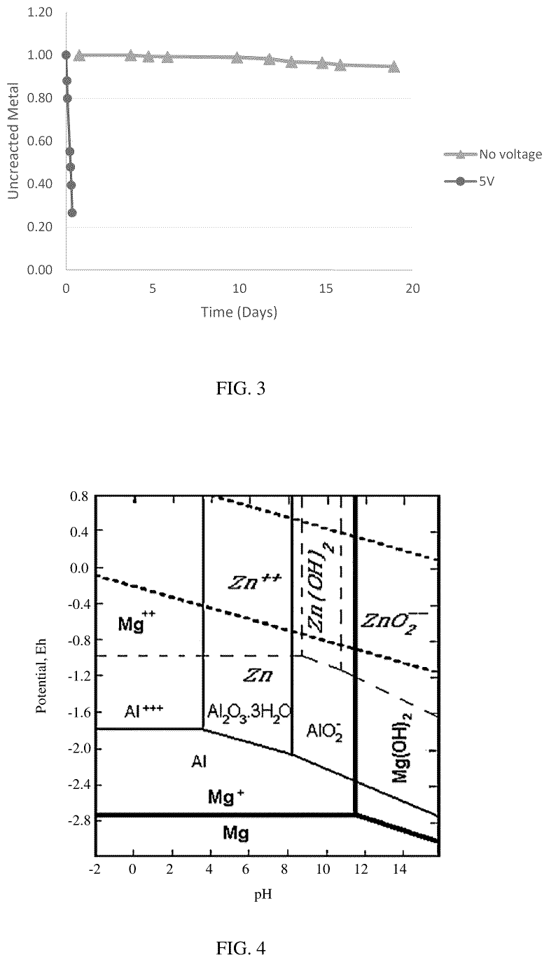

FIG. 3 illustrates a graph illustrating the effects of applying voltage to an expandable metal;

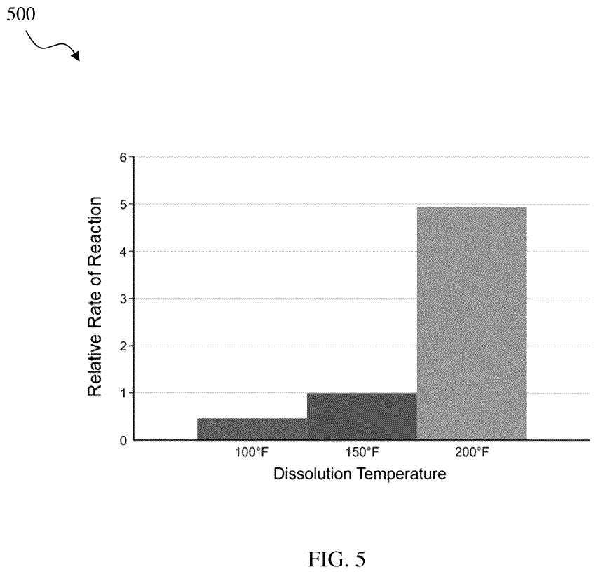

FIG. 4 illustrates a Pourbaix diagram for Mg, Al, and Zn;

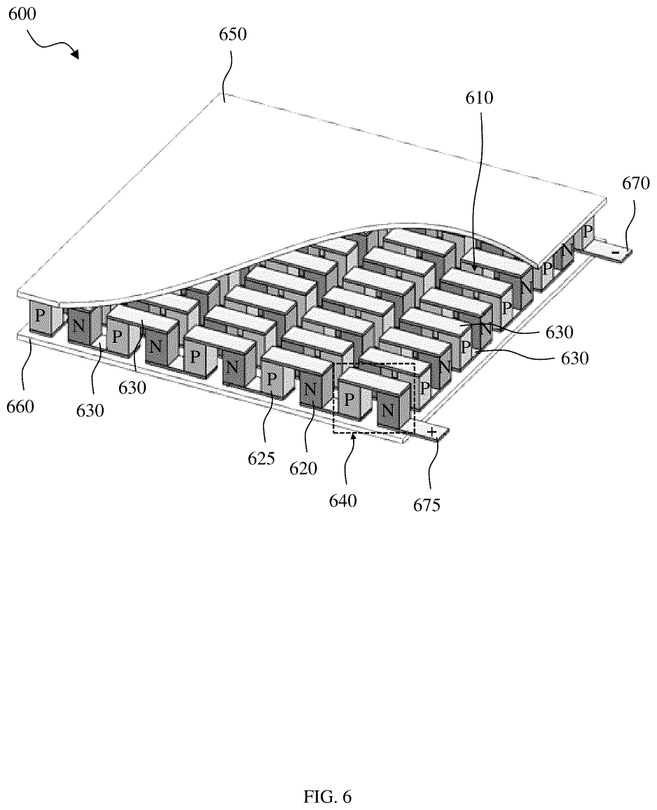

FIG. 5 illustrates a graph showing the relative rate of reaction for the expandable metals versus the dissolution temperature;

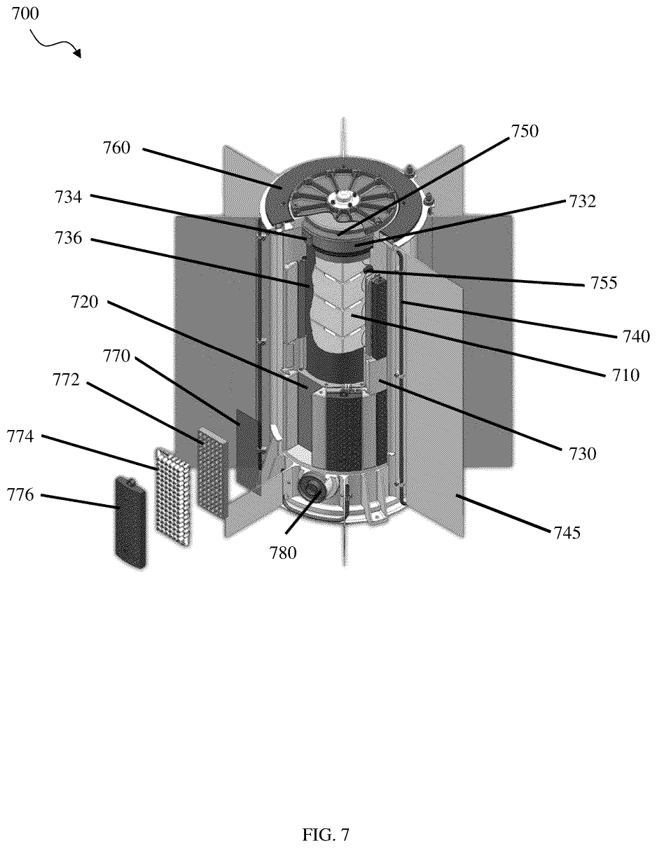

FIG. 6 illustrates one embodiment of a thermoelectric generator designed, manufactured and/or operated according to one or more embodiments of the disclosure;

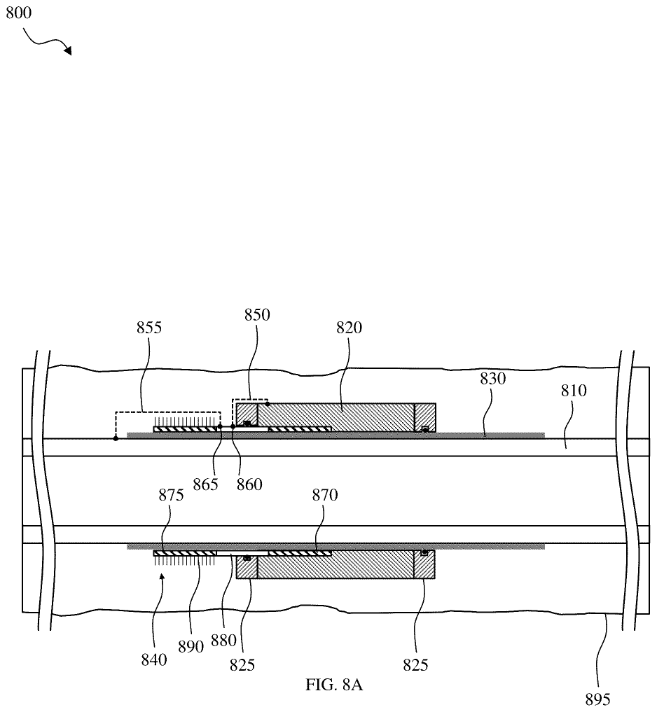

FIG. 7 illustrates a radioisotope thermoelectric generator designed, manufactured and/or operated according to one or more embodiments of the disclosure;

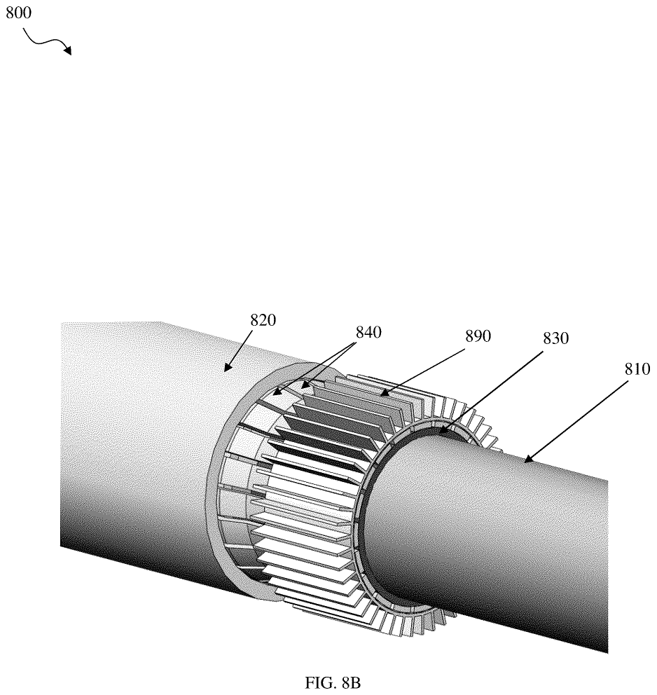

FIGS. 8A and 8B illustrate a cross-sectional view and a perspective view, respectively, of one embodiment of a downhole tool (e.g., packer, plug, anchor, etc.) designed, manufactured and/or operated according to one or more embodiments of the disclosure;

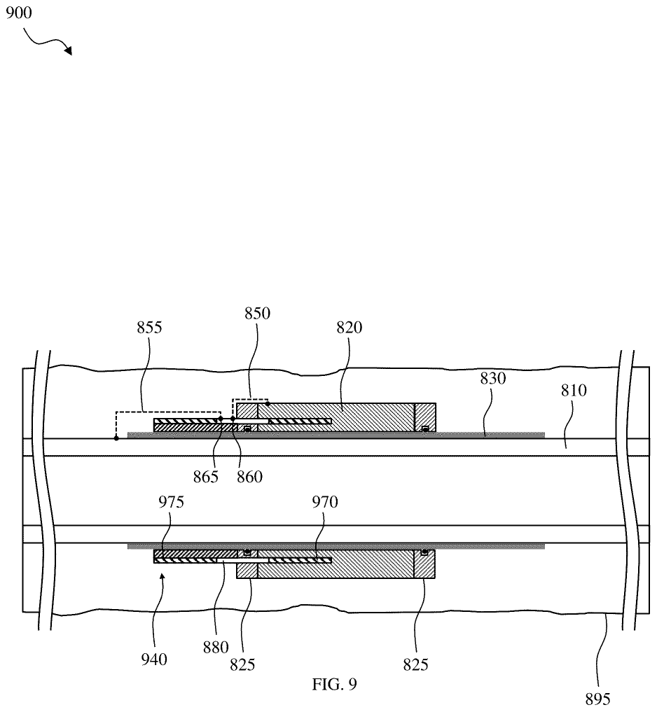

FIG. 9 illustrates a cross-sectional view of one embodiment of a downhole tool (e.g., packer, plug, anchor, etc.) designed, manufactured and/or operated according to one or more alternative embodiments of the disclosure;

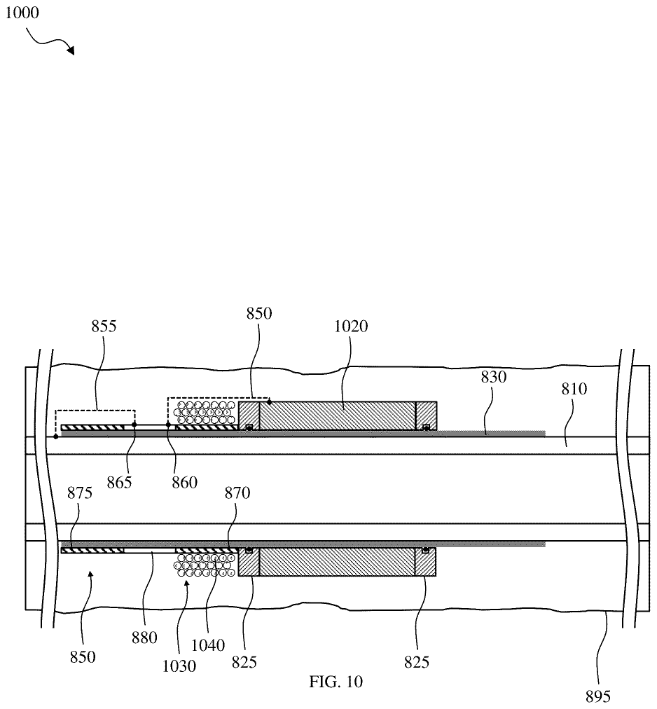

FIG. 10 illustrates a cross-sectional view of one embodiment of a downhole tool (e.g., packer, plug, anchor, etc.) designed, manufactured and/or operated according to one or more alternative embodiments of the disclosure;

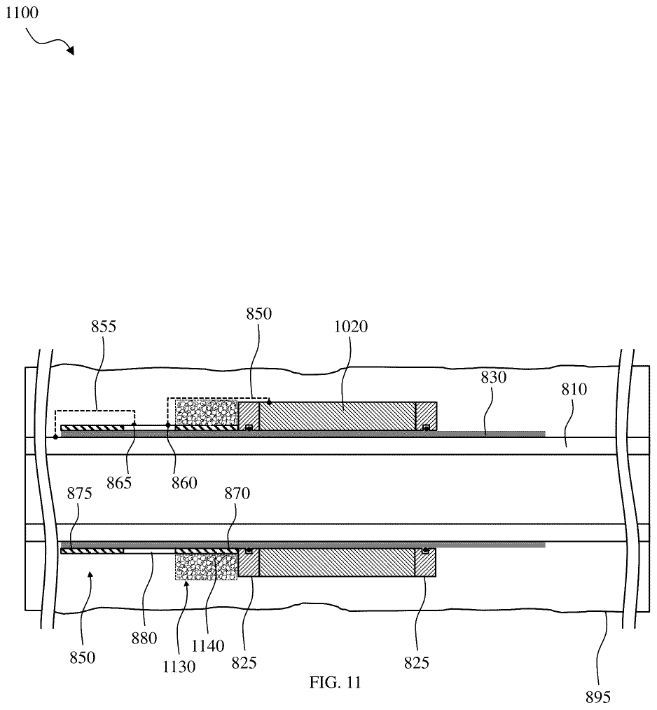

FIG. 11 illustrates a cross-sectional view of one embodiment of a downhole tool (e.g., packer, plug, anchor, etc.) designed, manufactured and/or operated according to one or more alternative embodiments of the disclosure;

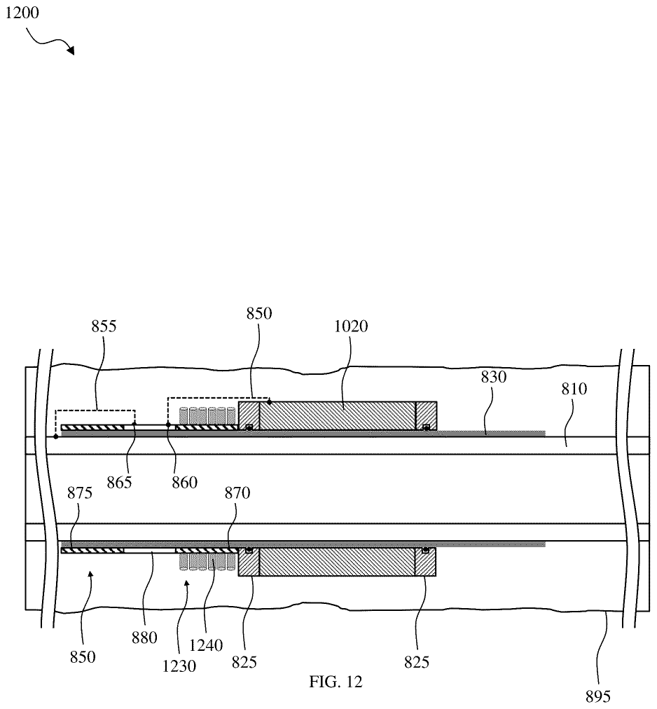

FIG. 12 illustrates a cross-sectional view of one embodiment of a downhole tool (e.g., packer, plug, anchor, etc.) designed, manufactured and/or operated according to one or more alternative embodiments of the disclosure;

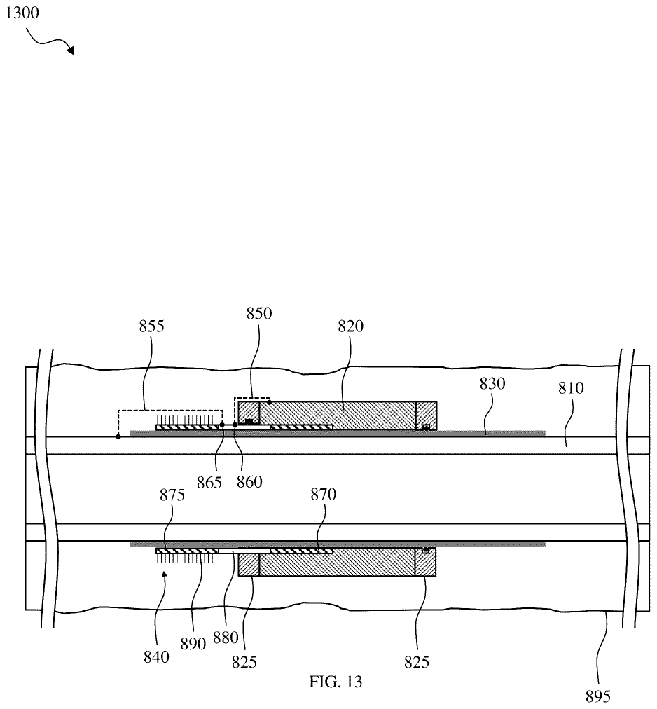

FIGS. 13 through 18 illustrate a method for deploying and/or setting a downhole tool designed, manufactured and/or operated according to one or more embodiments of the disclosure;

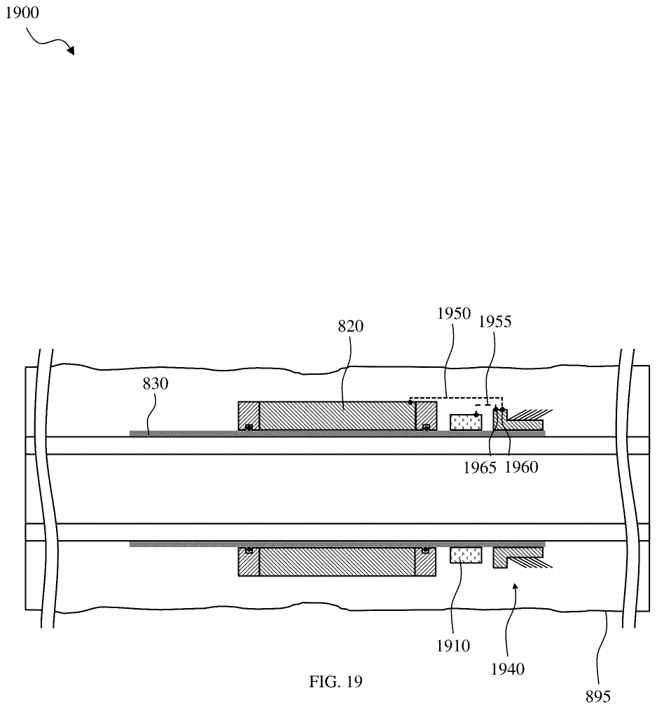

FIG. 19 illustrates a cross-sectional view of one embodiment of a downhole tool (e.g., packer, plug, anchor, etc.) designed, manufactured and/or operated according to one or more alternative embodiments of the disclosure;

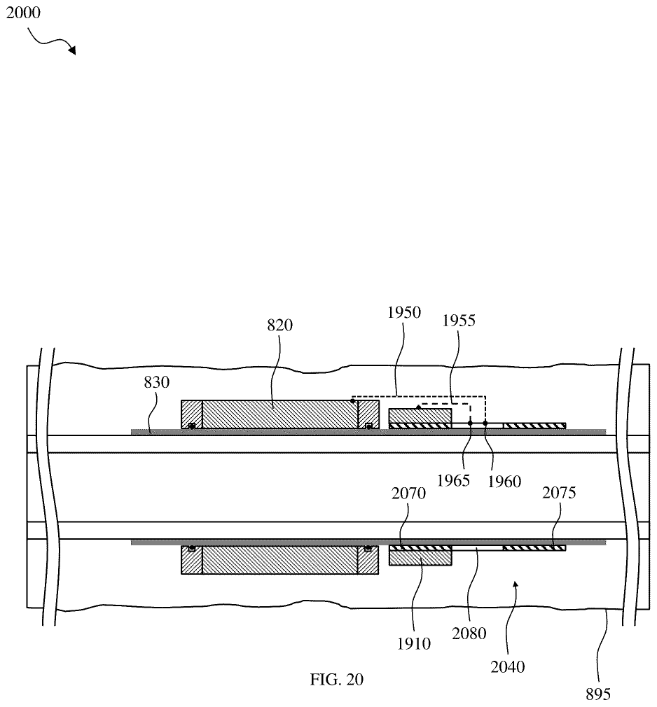

FIG. 20 illustrates a cross-sectional view of one embodiment of a downhole tool (e.g., packer, plug, anchor, etc.) designed, manufactured and/or operated according to one or more alternative embodiments of the disclosure;

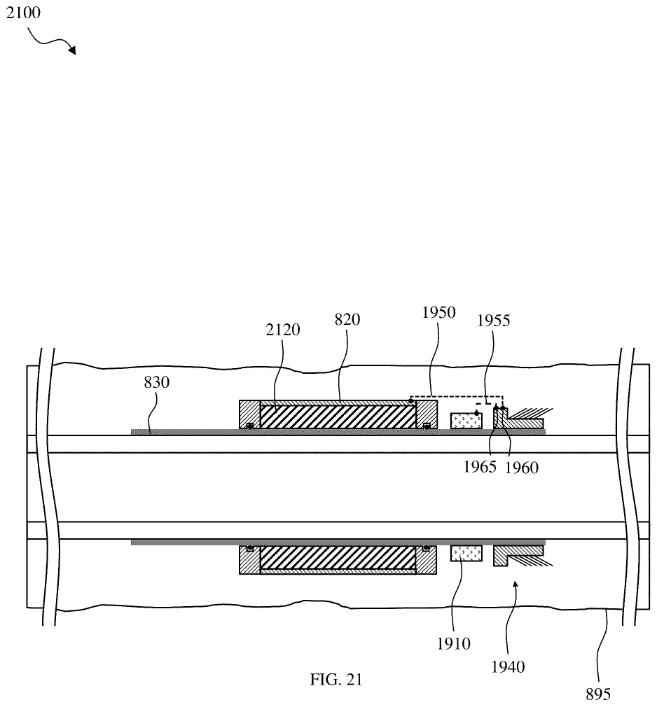

FIG. 21 illustrates a cross-sectional view of one embodiment of a downhole tool (e.g., packer, plug, anchor, etc.) designed, manufactured and/or operated according to one or more alternative embodiments of the disclosure;

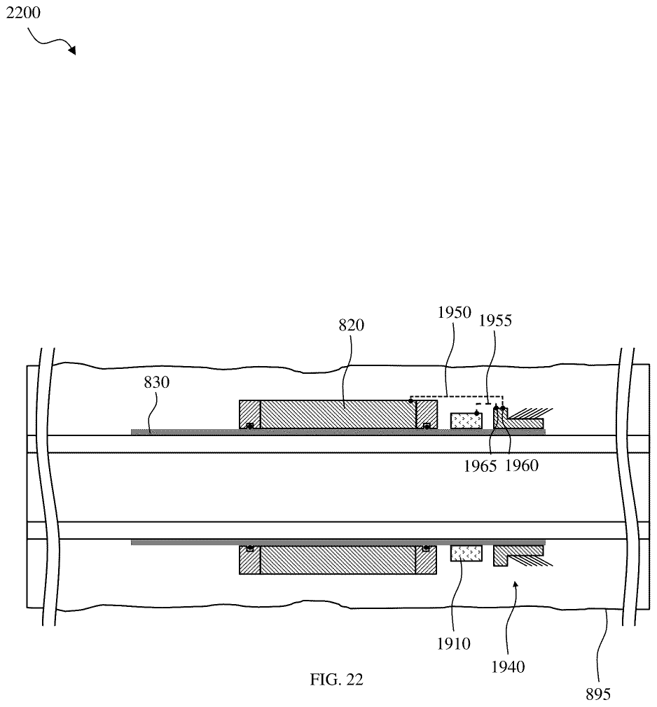

FIGS. 22 through 27 illustrate a method for deploying and/or setting a downhole tool designed, manufactured and/or operated according to one or more embodiments of the disclosure

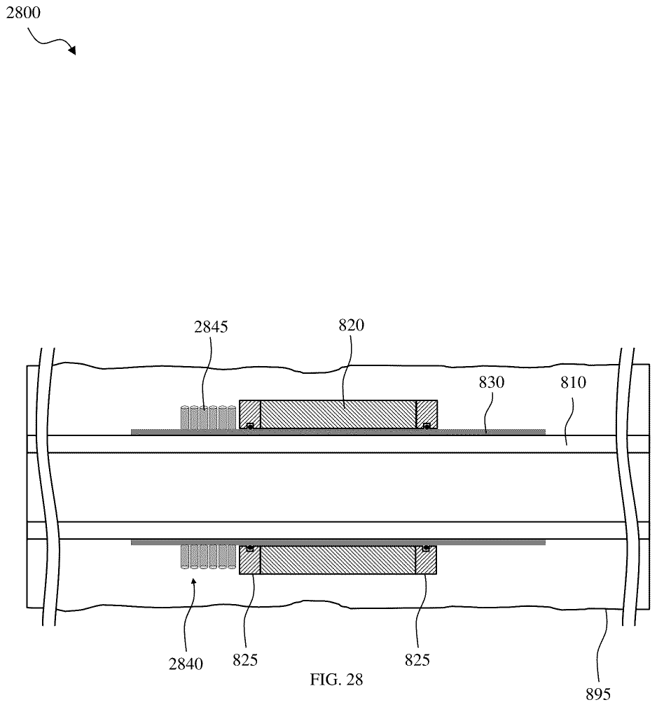

FIG. 28 illustrates a cross-sectional view of one embodiment of a downhole tool (e.g., packer, plug, anchor, etc.) designed, manufactured and/or operated according to one or more alternative embodiments of the disclosure;

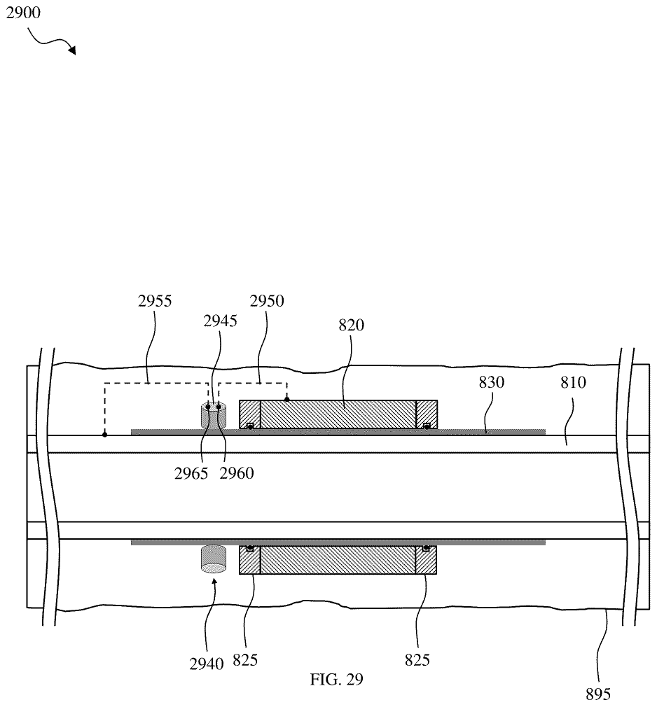

FIG. 29 illustrates a cross-sectional view of one embodiment of a downhole tool (e.g., packer, plug, anchor, etc.) designed, manufactured and/or operated according to one or more alternative embodiments of the disclosure;

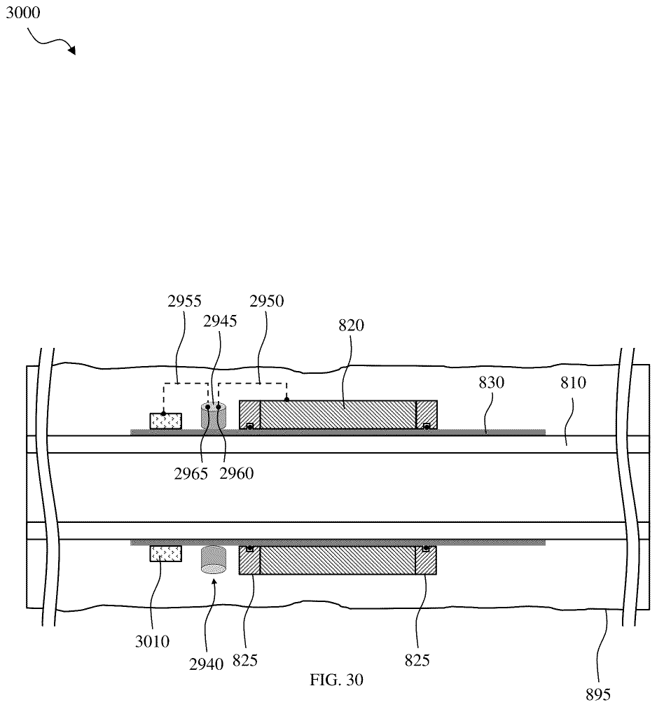

FIG. 30 illustrates a cross-sectional view of one embodiment of a downhole tool (e.g., packer, plug, anchor, etc.) designed, manufactured and/or operated according to one or more alternative embodiments of the disclosure;

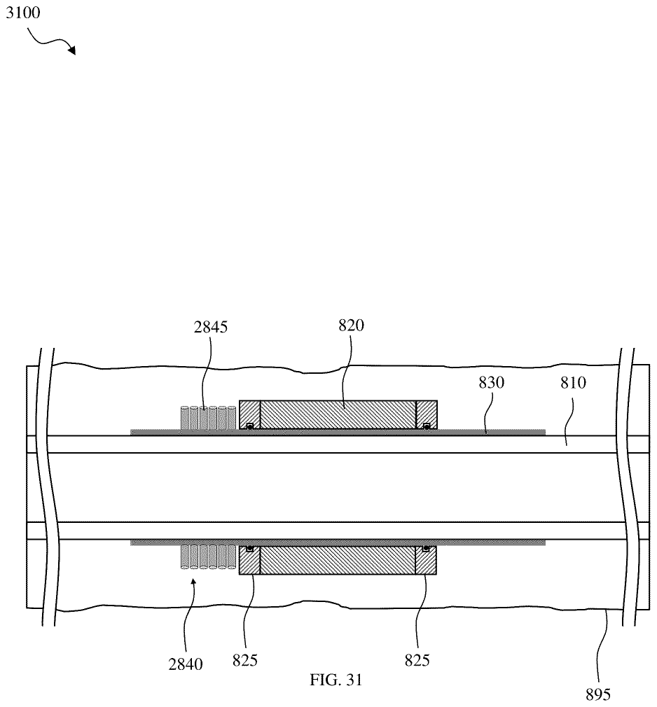

FIGS. 31 through 36 illustrate a method for deploying and/or setting a downhole tool designed, manufactured and/or operated according to one or more embodiments of the disclosure; and

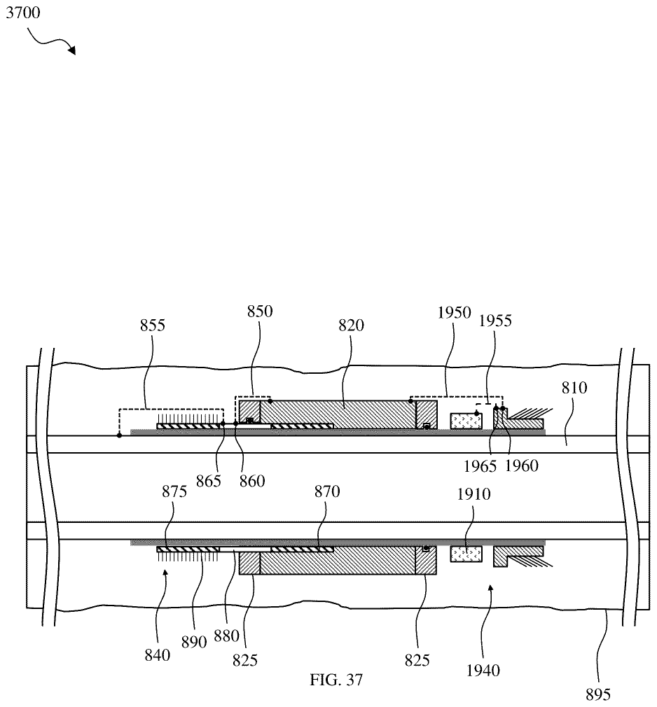

FIG. 37 illustrates a cross-sectional view of one embodiment of a downhole tool (e.g., packer, plug, anchor, etc.) designed, manufactured and/or operated according to one or more alternative embodiments of the disclosure.

### DETAILED DESCRIPTION

In the drawings and descriptions that follow, like parts are typically marked throughout the specification and drawings with the same reference numerals, respectively. The drawn figures are not necessarily to scale. Certain features of the disclosure may be shown exaggerated in scale or in somewhat schematic form and some details of certain elements may not be shown in the interest of clarity and conciseness. The present disclosure may be implemented in embodiments of different forms.

Specific embodiments are described in detail and are shown in the drawings, with the understanding that the present disclosure is to be considered an exemplification of the principles of the disclosure, and is not intended to limit the disclosure to that illustrated and described herein. It is to be fully recognized that the different teachings of the embodiments discussed herein may be employed separately or in any suitable combination to produce desired results.

Unless otherwise specified, use of the terms “connect,” “engage,” “couple,” “attach,” or any other like term describing an interaction between elements is not meant to limit the interaction to direct interaction between the elements and may also include indirect interaction between the elements described. Unless otherwise specified, use of the terms “up,” “upper,” “upward,” “uphole,” “upstream,” or other like terms shall be construed as generally away from the bottom, terminal end of a well, regardless of the wellbore orientation; likewise, use of the terms “down,” “lower,” “downward,” “downhole,” “downstream,” or other like terms shall be construed as generally toward the bottom, terminal end of a well, regardless of the wellbore orientation. Use of any one or more of the foregoing terms shall not be construed as denoting positions along a perfectly vertical or horizontal axis. Unless otherwise specified, use of the term “subterranean formation” shall be construed as encompassing both areas below exposed earth and areas below earth covered by water, such as ocean or fresh water.

Various values and/or ranges may be explicitly disclosed in certain embodiments herein. However, values/ranges from any lower limit may be combined with any upper limit to recite a range not explicitly recited. Similarly, values/ranges from any lower limit may be combined with any other lower limit to recite a range not explicitly recited. In the same way, values/ranges from any upper limit may be combined with any other upper limit to recite a range not explicitly recited. Additionally, whenever a numerical range with a lower limit and an upper limit is disclosed, any number and any included range falling within the range are specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values even if not explicitly recited. Thus, every point or individual value may serve as its own lower or upper limit combined with any other point or individual value or any other lower or upper limit, to recite a range not explicitly recited. Similarly, an individual value disclosed herein may be combined with another individual value or range disclosed herein to form another range.

Referring to FIG. 1, depicted is a perspective view of a well system 100 including an exemplary operating environment that the devices/apparatuses, systems and methods disclosed herein may be employed. For example, the well system 100 could use a downhole tool according to any of the embodiments, aspects, applications, variations, designs, etc. disclosed in the following paragraphs. The term downhole tool, as used herein and without limitation, includes frac plugs, bridge plugs, packers, and other tools for fluid isolation, as well as wellbore anchors, among many other downhole tools employing expandable metal. In fact, the downhole tool could be any tool that employs expandable metal.

The well system 100 illustrated in the embodiment of FIG. 1 includes a wellbore 120 extending through one or more subterranean formations 130. As those skilled in the art appreciate, the wellbore 120 may be fully cased, partially cased, or an open hole wellbore. In the illustrated embodiment of FIG. 1, the wellbore 120 is partially cased, and thus includes a cased region 140 and an open hole region 145. The cased region 140, as is depicted, may employ casing 150 that is held into place by cement 160.

The well system 100 illustrated in FIG. 1 additionally includes a downhole conveyance 170 deploying a downhole tool assembly 180 within the wellbore 120. The downhole conveyance 170 can be, for example, tubing-conveyed, wireline, slickline, work string, or any other suitable means for conveying the downhole tool assembly 180 into the wellbore 120. In one particular advantageous embodiment, the downhole conveyance 170 is American Petroleum Institute “API” pipe, but in another embodiment the downhole conveyance 170 is coiled tubing, among others.

The downhole tool assembly 180, in the illustrated embodiment, includes a first downhole tool 185 and a second downhole tool 190 (e.g., wellbore anchor). The first downhole tool 185 may comprise any downhole tool that could be positioned within a wellbore. Certain downhole tools that may find particular use in the well system 100 include, without limitation, scaling elements, sealing packers, elastomeric sealing packers, non-elastomeric sealing packers (e.g., including plastics such as PEEK, metal packers such as inflatable metal packers, as well as other related packers), liners, an entire lower completion, one or more tubing strings, one or more screens, one or more production sleeves, etc., The second downhole tool 190 (e.g., wellbore anchor) may comprise any wellbore anchor that could anchor the first downhole tool 185 within a wellbore. In certain embodiments, the first downhole tool 185 is deployed without the second downhole tool 190 (e.g., wellbore anchor), and in certain other embodiments the second downhole tool 190 (e.g., wellbore anchor) is deployed without the first downhole tool 185.

In accordance with the disclosure, at least a portion of the first downhole tool 185 or the second downhole tool 190 may include expandable metal. In some embodiments, all or part of the first downhole tool 185 or the second downhole tool 190 may be fabricated using expandable metal configured to expand in response to hydrolysis. The term expandable metal, as used herein, refers to the expandable metal in a pre-expansion form. Similarly, the term expanded metal, as used herein, refers to the resulting expanded metal after the expandable metal has been subjected to reactive fluid, as discussed below. The expanded metal, in accordance with one or more aspects of the disclosure, comprises a metal that has expanded in response to hydrolysis.

In certain embodiments, the expanded metal includes residual unreacted metal. For example, in certain embodiments the expanded metal is intentionally designed to include the residual unreacted metal. The residual unreacted metal has the benefit of allowing the expanded metal to self-heal if cracks or other anomalies subsequently arise, or for example to accommodate changes in the tubular or housing diameter due to variations in temperature and/or pressure. Nevertheless, other embodiments may exist wherein no residual unreacted metal exists in the expanded metal. In at least one embodiment, the residual unreacted metal exists when the expandable metal has expanded into contact with another feature, such as another wellbore tubular, prior to all of the expandable metal reacting into expanded metal. In at least one other embodiment, the residual unreacted metal exists when the expandable metal has expanded to fill a volume, such as a volume within a wellbore, prior to all of the expandable metal reacting into expanded metal. Once the expanded metal has sealed against a surface or filled the volume, the reactive fluid may no longer reach the expandable metal, and the hydrolysis essentially ends, in some instances leaving the residual unreacted metal.

The expandable metal, in some embodiments, may be described as expanding to a cement like material, and thereby forming the required seal and/or anchor. In other words, the expandable metal goes from metal to micron-scale particles and then these larger micron-scale particles lock together to, in essence, seal and/or anchor two or more surfaces together. The reaction may, in certain embodiments, occur in less than 2 days in a reactive fluid and in certain temperatures. Nevertheless, the time of reaction may vary depending on the reactive fluid, the expandable metal used, the downhole temperature, the surface-area-to-volume ratio (SA:V) of the expandable metal, etc., and the use of any one or more of the different thermoelectric generators, flow based generators, or generators comprising the radioisotope heater unit or the radioisotope thermoelectric generator, as disclosed herein.

In some embodiments, the reactive fluid may be a brine solution, such as may be produced during well completion activities, and in other embodiments, the reactive fluid may be one of the additional solutions discussed herein (e.g., water-based mud). The expandable metal is electrically conductive in certain embodiments. The expandable metal, in certain embodiments, has a yield strength greater than about 8,000 psi, e.g., 8,000 psi+/−50%. The expandable metal, in at least one embodiment, has a minimum dimension greater than about 1.25 mm (e.g., approximately 0.05 inches).

The hydrolysis of the expandable metal can create a metal hydroxide. The formative properties of alkaline earth metals (Mg-Magnesium, Ca-Calcium, etc.) and transition metals (Zn—Zinc, Al—Aluminum, etc.) under hydrolysis reactions demonstrate structural characteristics that are favorable for use with the present disclosure. Hydration results in an increase in size from the hydration reaction and results in a metal hydroxide that can precipitate from the fluid.

It should be noted that the starting expandable metal, unless otherwise indicated, is not a metal oxide (e.g., an insulator). In contrast, the starting expandable metal has, in certain embodiments, the properties of traditional metals: 1) highly conductive to both electricity and heat (e.g., greater than 1,000,000 siemens per meter); 2) contains a metallic bond (e.g., the outermost electron shell of each of the metal atoms overlaps with a large number of neighboring atoms), and as a consequence, the valence electrons are allowed to move from one atom to another and are not associated with any specific pair of atoms, which gives metals their conductive nature; 3) malleable and ductile, for example deforming under stress without cleaving; and 4) tends to be shiny and lustrous with high density. In contrast, metal oxides are ceramics, and are dull, insulating, fragile, brittle and are not conductive metals.

The hydration reactions for magnesium is:

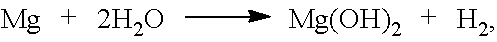

where Mg(OH)₂ is also known as brucite. Another hydration reaction uses aluminum hydrolysis. The reaction forms a material known as Gibbsite, bayerite, bochmite, aluminum oxide, and norstrandite, depending on form. The possible hydration reactions for aluminum are:

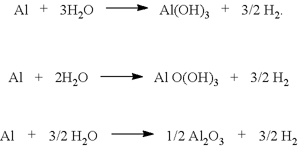

Magnesium hydroxide is considered to be relatively insoluble in water. Aluminum hydroxide can be considered an amphoteric hydroxide, which has solubility in strong acids or in strong bases. Alkaline earth metals (e.g., Mg, Ca, etc.) work well for the expandable metal, but transition metals (Al, etc.) also work well for the expandable metal. In one embodiment, the metal hydroxide is dehydrated by the swell pressure to form a metal oxide.

It is to be understood, that in certain embodiments the chosen expandable metal is to be selected such that the expanded metal does not degrade into the reactive fluid. As such, the use of metals or metal alloys for the expandable metal that form relatively water-insoluble hydration products may be chosen. For example, magnesium hydroxide and calcium hydroxide have low solubility in water. Alternatively, or in addition to, the sealing element may be positioned such that degradation into the reactive fluid is constrained due to the geometry of the area in which the expandable metal is disposed and thus resulting in reduced exposure of the expandable metal and/or expanded metal. For example, the volume of the area in which the expandable metal is disposed may be less than the expansion volume of the expandable metal. In some examples, the volume of the area is less than as much as 50% of the expansion volume. Alternatively, the volume of the area in which the expandable metal may be disposed may be less than 90% of the expansion volume, less than 80% of the expansion volume, less than 70% of the expansion volume, or less than 60% of the expansion volume.

In at least one embodiment, the expandable metal is a non-graphene based expandable metal. By non-graphene based material, it is meant that is does not contain graphene, graphite, graphene oxide, graphite oxide, graphite intercalation, or in certain embodiments, compounds and their derivatized forms to include a function group, e.g., including carboxy, epoxy, ether, ketone, amine, hydroxy, alkoxy, alkyl, aryl, aralkyl, alkaryl, lactone, functionalized polymeric or oligomeric groups, or a combination comprising at least one of the forgoing functional groups. In at least one other embodiment, the expandable metal does not include a matrix material or an exfoliatable graphene-based material. By not being exfoliatable, it means that the expandable metal is not able to undergo an exfoliation process. Exfoliation as used herein refers to the creation of individual sheets, planes, layers, laminac, etc. (generally, “layers”) of a graphene-based material; the delamination of the layers; or the enlargement of a planar gap between adjacent ones of the layers, which in at least one embodiment the expandable metal is not capable of.

In yet another embodiment, the expandable metal does not include graphite intercalation compounds, wherein the graphite intercalation compounds include intercalating agents such as, for example, an acid, metal, binary alloy of an alkali metal with mercury or thallium, binary compound of an alkali metal with a Group V element (e.g., P, As, Sb, and Bi), metal chalcogenide (including metal oxides such as, for example, chromium trioxide, PbO₂, MnO₂, metal sulfides, and metal selenides), metal peroxide, metal hyperoxide, metal hydride, metal hydroxide, metals coordinated by nitrogenous compounds, aromatic hydrocarbons (benzene, toluene), aliphatic hydrocarbons (methane, ethane, ethylene, acetylene, n-hexane) and their oxygen derivatives, halogen, fluoride, metal halide, nitrogenous compound, inorganic compound (e.g., trithiazyl trichloride, thionyl chloride), organometallic compound, oxidizing compound (e.g., peroxide, permanganate ion, chlorite ion, chlorate ion, perchlorate ion, hypochlorite ion, As₂O₅, N₂O₅, CH_{3D}IO₄, (NH₄)₂S₂O₈, chromate ion, dichromate ion), solvent, or a combination comprising at least one of the foregoing. Thus, in at least one embodiment, the expandable metal is a structural solid expanded metal, which means that it is a metal that does not exfoliate and it does not intercalate. In yet another embodiment, the expandable metal does not swell by sorption.

In an embodiment, the expandable metal used can be a metal alloy. The expandable metal alloy can be an alloy of the base expandable metal with other elements in order to either adjust the strength of the expandable metal alloy, to adjust the reaction time of the expandable metal alloy, or to adjust the strength of the resulting metal hydroxide byproduct, among other adjustments. The expandable metal alloy can be alloyed with elements that enhance the strength of the metal such as, but not limited to, Al—Aluminum, Zn—Zinc, Mn—Manganese, Zr—Zirconium, Y—Yttrium, Nd—Neodymium, Gd—Gadolinium, Ag—Silver, Ca—Calcium, Sn—Tin, and Re—Rhenium, Cu—Copper. In some embodiments, the expandable metal alloy can be alloyed with a dopant that promotes corrosion, such as Ni—Nickel, Fe—Iron, Cu—Copper, Co—Cobalt, Ir—Iridium, Au—Gold, C—Carbon, Ga—Gallium, In—Indium, Mg—Mercury, Bi—Bismuth, Sn—Tin, and Pd—Palladium. The expandable metal alloy can be constructed in a solid solution process where the elements are combined with molten metal or metal alloy. Alternatively, the expandable metal alloy could be constructed with a powder metallurgy process. The expandable metal can be cast, forged, extruded, sintered, welded, mill machined, lathe machined, stamped, eroded or a combination thereof. The metal alloy can be a mixture of the metal and metal oxide. For example, a powder mixture of aluminum and aluminum oxide can be ball-milled together to increase the reaction rate. Based upon the present disclosure, those skilled in the art would understand the ratios of the expandable metal to the alloy that might be necessary and/or achievable.

Optionally, non-expanding components may be added to the starting metallic materials. For example, ceramic, elastomer, plastic, epoxy, glass, or non-reacting metal components can be embedded in the expandable metal or coated on the surface of the expandable metal. In yet other embodiments, the non-expanding components are metal fibers, a composite weave, a polymer ribbon, or ceramic granules, among others. Alternatively, the starting expandable metal may be the metal oxide. For example, calcium oxide (CaO) with water will produce calcium hydroxide in an energetic reaction. Due to the higher density of calcium oxide, this can have a 260% volumetric expansion where converting 1 mole of CaO goes from 9.5 cc to 34.4 cc of volume. In one variation, the expandable metal is formed in a serpentinite reaction, a hydration and metamorphic reaction. In one variation, the resultant material resembles a mafic material. Additional ions can be added to the reaction, including silicate, sulfate, aluminate, and phosphate. The expandable metal can be alloyed to increase the reactivity or to control the formation of oxides.

The expandable metal can be configured in many different fashions, as long as an adequate volume of material is available for achieving the necessary seal and/or anchor. For example, the expandable metal may be formed into a single long member, multiple short members, rings, among others. In another embodiment, the expandable metal may be formed into a long wire of expandable metal, which can in turn be wound around a housing as a sleeve, or placed within a seal groove (e.g., thereby forming a continuous wire of expandable metal). The wire diameters do not need to be of circular cross-section, but may be of any cross-section. For example, the cross-section of the wire could be oval, rectangle, star, hexagon, keystone, hollow braided, woven, twisted, among others, and remain within the scope of the disclosure. In certain other embodiments, the expandable metal is a collection of individual separate chunks of the metal held together with a binding agent. In yet other embodiments, the expandable metal is a collection of individual separate chunks of the metal that are not held together with a binding agent, but held in place using one or more different techniques, including an enclosure (e.g., an enclosure that could be crushed to expose the individual separate chunks to the reactive fluid), a cage, etc.

Additionally, a delay coating or protective layer may be applied to one or more portions of the expandable metal to delay the expanding reactions. In one embodiment, the material configured to delay the hydrolysis process is a fusible alloy. In another embodiment, the material configured to delay the hydrolysis process is a eutectic material. In yet another embodiment, the material configured to delay the hydrolysis process is a wax, oil, or other non-reactive material. The delay coating or protective layer may be applied to any of the different expandable metal configurations disclosed above.

Ultimately, different expandable metals have different amounts of volumetric expansion that they may achieve. Accordingly, if the volume of space that the expandable metal is located is small enough such that the expandable metal expands into contact with the one or more surfaces upon undergoing hydrolysis, while volumetrically expanding no more than its total achievable volumetric expansion, then the resulting expanded metal will function as an anchor and/or seal. However, if the volume of space were so large that the expandable metal volumetrically expands its full achievable volumetric expansion upon undergoing hydrolysis without yet expanding into contact with the one or more surfaces, then it would degrade/dissolve and go away.

For example, as discussed above, calcium oxide (CaO) in one embodiment has a total achievable volumetric expansion of about approximately 260%. Accordingly, if the volume of space is small enough such that the calcium oxide (CaO) expands into contact with the one or more surfaces upon undergoing hydrolysis, while volumetrically expanding less than 260%, then the resulting expanded metal will function as an anchor and/or seal. However, if the volume of space were so large that the calcium oxide (CaO) volumetrically expanded the full 260% upon undergoing hydrolysis without yet expanding into contact with the one or more surfaces, then it would degrade/dissolve and go away. Other expandable metals have different total achievable expansion amounts, but one skilled in the art would be able to apply the principles taught herein to those other materials, while dictating whether the expandable metal will ultimately form an anchor and/or seal, or degrade/dissolve and go away.

Given the foregoing, at least a portion of the downhole tool assembly 180 should be designed such that the expandable metal ultimately acts as an anchor/seal in those applications where it is necessary for the expandable metal to act as an anchor/seal, including calculating the amount of expandable metal necessary for a given volume of space for the expandable metal to ultimately end up as the anchor/seal.

In application, the downhole tool assembly 180 can be moved down the wellbore 120 via the downhole conveyance 170 to a desired location. Once the downhole tool assembly 180, including the first downhole tool 185 and/or the second downhole tool 190 reaches the desired location, one or both of the first downhole tool 185 and/or the second downhole tool 190 may be set in place according to the disclosure. In one embodiment, one or both of the first downhole tool 185 and/or the second downhole tool 190 include the expandable metal, and thus are subjected to a wellbore fluid (e.g., reactive fluid) sufficient to expand the expandable metal into contact with a nearby surface, and thus in certain embodiments seal and/or anchor the one or more downhole tools within the wellbore.

In the embodiment of FIG. 1, the first downhole tool 185 and/or the second downhole tool 190 are positioned in the open hole region 145 of the wellbore 120. The first downhole tool 185 and/or the second downhole tool 190 including the expandable metal are particularly useful in open hole situations, as the expandable metal is well suited to adjust to the surface irregularities that may exist in open hole situations. Moreover, the expandable metal, in certain embodiments, may penetrate into the formation of the open hole region 145 and create a bond into the formation, and thus not just at the surface of the formation. Notwithstanding the foregoing, the first downhole tool 185 and/or the second downhole tool 190 are also suitable for a cased region 140 of the wellbore 120.

In certain embodiments, it is desirable or necessary to accelerate and/or decelerate the expansion of the expandable metal (e.g., increase or decrease a rate of reaction of the hydrolysis). The present disclosure has recognized that a voltage (e.g., provided via a power source, whether uphole or downhole) may be used to increase or decrease a rate of reaction of the hydrolysis. Accordingly, the applied voltage may be used to accelerate and/or decelerate the setting of any downhole tool that includes the expandable metal. In accordance with one embodiment, a first electrode is located between a first connection of a power source and the expandable metal, and a second electrode is located between a second connection of the power source and a downhole conductive feature. In accordance with this embodiment, the expandable metal is a first side of the electrical circuit, wherein the downhole conductive feature is the second side of the electrical circuit. In at least one embodiment, the electrodes are configured so that at least part of the electrical current passes through fluid surrounding the expandable metal. For example, at least a portion of one or both of the first electrode or the second electrode could be exposed to the wellbore fluid surrounding the expandable metal.

A positive voltage may be applied so that the expandable metal spends at least part of its time as an anode of the circuit. In one embodiment, the positive voltage accelerates the expansion process by up to at least 2×. In another embodiment, the positive voltage accelerates the expansion process by up to at least 5×. In yet another embodiment, the positive voltage accelerates the expansion process by up to at least 10×, and in yet another embodiment of 20× or 100×, or more.

In another embodiment, a negative voltage may be applied so that the expandable metal spends at least part of its time as a cathode of the circuit. In one embodiment, the negative voltage decelerates the expansion process by up to at least 2×. In another embodiment, the negative voltage protects the expanded metal from acid corrosion. For example, a voltage of −2.8 volts may be used to protect a magnesium containing expandable metal from corrosion, a voltage of −1.8 volts may be used to protect an aluminum containing expandable metal from corrosion, and a voltage of −1 volts may be used to protect a zinc containing expandable metal from corrosion, among others.

The electrical power can be applied from many different types of power sources. For example, in at least one embodiment, the power source is flow based generator. For example, the flow based generator may be a hydroelectric generator, a piezoelectric impulse generator, a thermoelectric generator, or a radioisotope generator, among others, and remain within the scope of the disclosure. The voltage, in at least one embodiment, is between 0.01 volts and 200 volts. In yet another embodiment, the voltage is between 0.5 volts and 10 volts. In at least one embodiment, the electrical current is between 0.5 milliamps and 100 amps, and in yet another embodiment is between 0.05 amps and 5 amps.

The present disclosure has additionally recognized that increased temperatures may be used to accelerate the expansion process, and thus accelerate the setting of any downhole tool including the expandable metal. For example, the present disclosure has recognized that a downhole localized heater may be used to provide a localized temperature spike to accelerate the expansion process, for example by way of an acceleration of the galvanic reaction. Accordingly, in certain embodiments, the expandable metal may be set on command, for example as easily as hitting a button that enables the downhole localized heater. The ability to set the expandable metal on command has increasing importance for creating packers, liner coupling, multilateral junctions, anchors, and downhole seals, among other downhole tools and/or features including expandable metal.

In accordance with one embodiment of the disclosure, a radioisotope generator comprising a radioisotope heater unit may be positioned proximate the one or more expandable members. The radioisotope generator comprising a radioisotope heater unit, in this embodiment, is configured to provide a localized temperature spike to accelerate the expansion process of the one or more expandable members, for example by way of an acceleration of the galvanic reaction. The term temperature spike, as used herein, means the radioisotope generator comprising a radioisotope heater unit is configured to provide an increase (e.g., localized increase) in temperature of at least 10° C. In yet another embodiment, the radioisotope generator comprising a radioisotope heater unit is configured to provide a temperature spike of at least 25° C. In yet another embodiment, the radioisotope generator comprising a radioisotope heater unit is configured to provide a temperature spike of at least 50° C. In yet another embodiment, the radioisotope generator comprising a radioisotope heater unit is configured to provide a temperature spike of at least 100° C. In one embodiment, the radioisotope generator comprising a radioisotope heater unit accelerates the expansion process by up to at least 2×. In another embodiment, the radioisotope generator comprising a radioisotope heater unit accelerates the expansion process by up to at least 5×. In yet another embodiment, the radioisotope generator comprising a radioisotope heater unit accelerates the expansion process by up to at least 10×, and in yet another embodiment of 20× or 100×, or more.

Referring to FIG. 2, depicted is a perspective view of an alternative embodiment of a well system 200 including an exemplary operating environment that the apparatuses, systems and methods disclosed herein may be employed. The well system 200 is similar in many respects to the well system 100. Accordingly, like reference numbers have been used to indicate similar, if not identical, features. The well system 200, in contrast to the well system 100, includes a wellbore tubular 210 (e.g., liner hanger) extending from the casing 150 into the open hole region 145. The well system 200 additionally includes one or more downhole packers 220 located in the open hole region 145, thereby isolating the various different production zones within the well system 200. In accordance with at least one embodiment, the one or more downhole packers 220 may include the expandable metal configured to expand in response to hydrolysis in accordance with the disclosure. Additionally, the one or more downhole packers 220 are operable to receive a voltage or temperature spike as the expandable metal is expanding in response to wellbore fluid, as contemplated herein.

An experiment was conducted, wherein the reaction time of the expandable metal was compared between an applied voltage and no voltage. The mass of the unreacted metal is shown in FIG. 3. As illustrated, applying just a 5 volt signal greatly accelerated the reaction rate.

In an alternative embodiment, the opposite voltage is used to delay the initiation of the chemical reaction. Thus, while applying a positive voltage accelerates the chemical reaction, applying a negative voltage to the expandable metal will inhibit the reaction. This can ensure that the expandable metal does not react (e.g., expand) until a desired time or more desirable time. Additionally, the negative voltage can protect the metal from acid based corrosion.

A Pourbaix diagram for Mg, Al, and Zn are shown in FIG. 4. Aluminum, magnesium, and zinc will normally dissolve when exposed to acid (pH=0). If a negative voltage is applied to the expandable metal, then the expandable metal will be immune from corrosion. As shown in FIG. 4, applying −2.8V will protect Mg. Applying −1.8V will protect Al. Applying −1V will protect Zn. In one embodiment, a negative voltage is used to delay the reaction of the expandable metal for one period of time and then a positive voltage is used to accelerate the reaction of the expandable metal for a second period of time.

Turning briefly to FIG. 5, illustrated is a graph 500 showing the relative rate of reaction for the expandable metals versus the dissolution temperature. As is evident from FIG. 5, the relative rate of reaction increases substantially (e.g., possibly exponentially) as the dissolution temperature increases. For example, at a dissolution temperature of about 38° C. (e.g., about 100° F.) the relative rate of reaction is about 0.5. However, at a dissolution temperature of about 66° C. (e.g., about 150° F.) the relative rate of reaction is about 1, and moreover at a dissolution temperature of about 93° C. (e.g., about 200° F.) the relative rate of reaction is almost 5.

Turning to FIG. 6, illustrated is one embodiment of a thermoelectric generator 600 designed, manufactured and/or operated according to one or more embodiments of the disclosure. The thermoelectric generator 600, in one or more embodiments, includes a collection of thermoelements (e.g., n-type semiconductors 620 and p-type semiconductors 625) interconnected with each other to form a thermoelectric module 610. The n-type semiconductors 620 and p-type semiconductors 625 may be obtained by doping different foreign atoms into thermoelectric semiconductor materials. In n-type semiconductors 620, the heat/emf force is carried by free electrons, while in p-type semiconductors 625, it is carried by holes.

The thermoelectric effect, in at least one embodiment, occurs when the n-type semiconductors 620 and p-type semiconductors 625 (thermoelements) are connected with each other with conductors 630, ultimately resulting in a thermocouple 640. In almost all applications, a single thermocouple 640 cannot meet the desired power generation or the desired heating-cooling requirement. Therefore, traditionally a plurality of the thermocouples 640 are brought together to create the thermoelectric module 610 when they are connected to each other with the conductors 630 (e.g., coupled electrically in series and thermally in parallel).

The thermoelectric generator 600, in at least the embodiment of FIG. 6, additionally includes a hot side thermal conductor 650 and a cold side thermal conductor 660. The hot side thermal conductor 650 and the cold side thermal conductor 660, in at least one embodiment, may comprise a ceramic, and furthermore may provide rigidity (e.g., strength) to the thermoelectric module 610, allowing the collection of thermoelements (e.g., n-type semiconductors 620 and p-type semiconductors 625) to stay together. Also, since the ceramic material has a high thermal conductivity coefficient and low electrical conductivity, it helps the outer part of the thermoelectric generator 600 to provide both electrical insulation and good heat transfer.

The thermoelectric generator 600, in at least the embodiment of FIG. 6, additionally includes a first terminal 670 (e.g., negative terminal) and a second terminal 675 (e.g., positive terminal) for coupling to an external downhole device. It should be noted that the thermoelectric generator 600 disclosed above with regard to FIG. 6 is but a single design that could be used. Accordingly, other embodiments with other different thermoelectric generators could be used and remain within the scope of the present disclosure. Thus, unless otherwise directed, the present disclosure should not be limited to any specific design and/or type of thermoelectric generator.

Turning to FIG. 7, illustrated is a radioisotope thermoelectric generator 700 designed, manufactured and/or operated according to one or more embodiments of the disclosure. The radioisotope thermoelectric generator 700, in one or more embodiments, initially includes a general purpose heat source, such as a collection of one or more radioisotope heating units 710. The one or more radioisotope heating units 710, in at least one embodiment, are coupled to a heat block 720. The one or more radioisotope heating units 710 and heat block 720, in one or more embodiments, are surrounded by a series of insulation features, including a first microtherm insulation 730, Min-K insulation 732, isolation bellows 734, isolation liner assembly 736. In addition, the radioisotope thermoelectric generator 700 may additionally include one or more cooling tubes 740, which in at least one embodiment may be coupled to a series of fins 745. In addition, the radioisotope thermoelectric generator 700 may additionally include a BiMetal ring 750, a getter assembly 755, a seal weld cover 760, and a collection of additional features, including mica 770, a second microtherm insulation 772, a thermoelectric couple assembly 774, and a modulation bar 776, among other features.

In at least one other embodiment, the radioisotope thermoelectric generator 700 may additionally include a power out receptacle 780, which may thereby include a first terminal (e.g., negative terminal not shown) and a second terminal (e.g., positive terminal not shown) for coupling to an external downhole device.

It should be noted that the radioisotope thermoelectric generator 700 disclosed above with regard to FIG. 7 is but a single design that could be used. Accordingly, other embodiments with other different radioisotope thermoelectric generators could be used and remain within the scope of the present disclosure. Thus, unless otherwise directed, the present disclosure should not be limited to any specific design and/or type of radioisotope thermoelectric generator.

Turning to FIGS. 8A and 8B, illustrated are a cross-sectional view and a perspective view, respectively, of one embodiment of a downhole tool 800 (e.g., packer, plug, anchor, etc.) designed, manufactured and/or operated according to one or more embodiments of the disclosure. The downhole tool 800, in at least one embodiment, is positioned within a wellbore 895. The downhole tool 800, in the illustrated embodiment, includes a downhole feature 810. In at least one embodiment, the downhole feature 810 is a downhole tubular, such as a downhole production tubular. In yet another embodiment, the downhole feature 810 is another downhole feature and/or other downhole tubular, or even a sacrificial expandable metal downhole feature (e.g., discussed further below).

In one or more embodiments, expandable metal 820 is positioned proximate the downhole feature 810. In accordance with the disclosure, as well as discussed in detail above, the expandable metal 820 is configured to expand in response to hydrolysis. In the illustrated embodiment of FIGS. 8A and 8B, the expandable metal 820 is bounded by a pair of end rings 825, and is placed on the downhole feature 810, for example with an insulating layer 830 disposed therebetween.

In the illustrated embodiment of FIGS. 8A and 8B, a power source (e.g., thermoelectric generator 840) is positioned proximate the expandable metal 820. Any type of thermoelectric generator 840 may be used and remain within the scope of the disclosure, including one somewhat similar to the thermoelectric generator 600 of FIG. 6. In accordance with at least one embodiment, a first electrode 850 is coupled between the expandable metal 820 and a first terminal 860 of the thermoelectric generator 840. In at least one embodiment, the first electrode 850 is configured to provide a voltage to the expandable metal 820 to increase or decrease a rate of reaction of the hydrolysis. In accordance with at least one other embodiment, a second electrode 855 is coupled between the downhole feature 810 and a second terminal 865 of the thermoelectric generator.

In at least one embodiment, the first terminal 860 is a positive terminal and the second terminal 865 is a negative terminal. In this embodiment, the first electrode 850 is coupled between the expandable metal 820 and the positive terminal of the thermoelectric generator 840, and the second electrode 855 is coupled between the downhole feature 810 and the negative terminal of the thermoelectric generator 840. In this scenario, the expandable metal 820 functions as an anode to increase the rate of reaction of the hydrolysis of the expandable metal 820, and the downhole feature 810 functions as a cathode.

In yet another embodiment, the first terminal 860 is a negative terminal and the second terminal 865 is a positive terminal. In this embodiment, the first electrode 850 is coupled between the expandable metal 820 and the negative terminal of the thermoelectric generator 840, and the second electrode 855 is coupled between the downhole feature 810 and the positive terminal of the thermoelectric generator 840. In this scenario, the expandable metal 820 functions as a cathode to decrease the rate of reaction of the hydrolysis of the expandable metal 820, and the downhole feature 810 functions as an anode. In at least this second embodiment, the downhole feature that the second electrode 855 couples to is a sacrificial downhole feature (e.g., sacrificial expandable metal downhole feature), as opposed to the downhole tubular illustrated. Notwithstanding the foregoing, the embodiment of FIGS. 8A and 8B envision that the downhole tool 800 will benefit from the increased rate of reaction of the hydrolysis, and thus the downhole tool 800 will likely be wired similar to the first example given above, and thus the first electrode 850 is coupled between the expandable metal 820 and the positive terminal of the thermoelectric generator 840, and the second electrode 855 is coupled between the downhole feature 810 and the negative terminal of the thermoelectric generator 840.

In at least one embodiment, the thermoelectric generator 840 includes a hot side thermal conductor 870 and a cold side thermal conductor 875 separated by a thermoelectric module 880, the thermoelectric module 880 including a plurality of n-type semiconductors and p-type semiconductors connected with each other, for example as discussed above. In one or more embodiments, the hot side thermal conductor 870 is coupled to the expandable metal 820, the expandable metal 820 configured to create a temperature differential between the hot side thermal conductor 870 and the cold side thermal conductor 875 during an exothermic electrolytic reaction associated with the hydrolysis of the expandable metal 820, thereby generating the voltage. In one or more embodiments, the hot side thermal conductor 870 is placed between the downhole feature 810 and the expandable metal 820. As discussed in greater detail below, the hot side thermal conductor 870 may be alternatively placed and remain within the scope of the disclosure. Ultimately, in at least one embodiment, the use of the thermoelectric generator 840 provides for a self-sustained downhole tool, wherein the heat inherently generated through the exothermic electrolytic reaction associated with the hydrolysis of the expandable metal 820 is converted to a voltage that is then applied back to the expandable metal 820 to increase the hydrolysis and thus expansion rate.

In the embodiment of FIGS. 8A and 8B, the downhole tool 800 additionally includes a fin structure 890 coupled with the cold side thermal conductor 875. In at least this one embodiment, the fin structure 890 is configured to amplify a temperature differential between the hot side thermal conductor 870 and the cold side thermal conductor 875 as relatively cooler fluid travels over the fin structure 890. Any type of heat sync, including the fin structure 890 depicted, may be used and remain within the scope of the disclosure.

In yet another embodiment, the cold side thermal conductor 875 could be exposed to or encased within a thermally poor conductor fluid. For example, in at least one embodiment the cold side thermal conductor 875 could be encased within silicon oil or PFPE oil, which would take a longer duration to equalize with the downhole temperatures, or less affected by the heat produced by the hydrolysis of the expandable metal 820, for example due to their poor conductive nature. These poor conductive fluids help maintain the temperature difference for a longer duration for the thermoelectric generator 840 to produce power (e.g., voltage) from the temperature difference.

Turning to FIG. 9, illustrated is a cross-sectional view of one embodiment of a downhole tool 900 (e.g., packer, plug, anchor, etc.) designed, manufactured and/or operated according to one or more alternative embodiments of the disclosure. The downhole tool 900 of FIG. 9 is similar in many respects to the downhole tool 800 of FIGS. 8A and 8B. Accordingly, like reference numbers may be used to indicate similar, if not identical, features. The downhole tool 900 differs from the downhole tool 800, for the most part, in that the downhole tool 900 employs a thermoelectric generator 940 that is at least partially embedded within the expandable metal 820. For example, in the embodiment of FIG. 9, a hot side thermal conductor 970 is embedded within the expandable metal 820, the expandable metal 820 configured to create a temperature differential between the hot side thermal conductor 970 and a cold side thermal conductor 975 during an exothermic electrolytic reaction associated with the hydrolysis of the expandable metal 820, for example to generate a voltage. Again, the voltage may be a positive voltage that increases the rate of reaction of the hydrolysis of the expandable metal 820, or alternatively a negative voltage that decreases the rate of reaction of the hydrolysis of the expandable metal 820.

Turning to FIG. 10, illustrated is a cross-sectional view of one embodiment of a downhole tool 1000 (e.g., packer, plug, anchor, etc.) designed, manufactured and/or operated according to one or more alternative embodiments of the disclosure. The downhole tool 1000 of FIG. 10 is similar in many respects to the downhole tool 800 of FIGS. 8A and 8B. Accordingly, like reference numbers may be used to indicate similar, if not identical, features. The downhole tool 1000 differs from the downhole tool 800, for the most part, in that the downhole tool 1000 employs a first expandable metal 1020 (e.g., similar to the expandable metal 820), but additionally includes a second expandable metal 1030 placed proximate thereto. In this configuration, the first expandable metal 1020 is configured to generate a first amount of heat during a first exothermic electrolytic reaction associated with the hydrolysis of the first expandable metal 1020, and the second expandable metal is configured to generate a second greater amount of heat during a second exothermic electrolytic reaction associated with the hydrolysis of the second expandable metal 1030. In at least this one embodiment, the hot side thermal conductor 870 is positioned more proximate the second expandable metal 1030 than the first expandable metal 1020. Accordingly, this configuration may provide a greater temperature differential between the hot side thermal conductor 870 and the cold side thermal conductor 875, and thus a greater supplied voltage (e.g., positive or negative) to the first expandable metal 1020.

The second expandable metal 1030 may comprise many different expandable metals and remain within the scope of the disclosure. In at least one embodiment, the first and second expandable metals 1020, 1030 comprise different materials that inherently provide the first amount of heat and second greater amount of heat. For example, the first expandable metal 1020 may comprise a first material configured to generate the first amount of heat and the second expandable metal 1030 may comprise a second different material configured to generate the second greater amount of heat In yet another embodiment, the first and second expandable metals 1020, 1030 comprise a same material, but the first expandable metal 1020 has a first surface area configured to generate the first amount of heat and the second expandable metal 1030 has a second greater surface area configured to generate the second greater amount of heat. In at least one embodiment, such as that shown, the second expandable metal 1030 is a wire of expandable metal 1040, thereby providing the second greater surface area.

Turning to FIG. 11, illustrated is a cross-sectional view of one embodiment of a downhole tool 1100 (e.g., packer, plug, anchor, etc.) designed, manufactured and/or operated according to one or more alternative embodiments of the disclosure. The downhole tool 1100 of FIG. 11 is similar in many respects to the downhole tool 1000 of FIG. 10. Accordingly, like reference numbers may be used to indicate similar, if not identical, features. The downhole tool 1100 differs from the downhole tool 1000, for the most part, in that the downhole tool 1100 employs a collection of chunks of expandable metal 1140 as its second expandable metal 1130. In at least one embodiment, the chunks of expandable metal 1140 are held together with a binding agent, but in other embodiments the chunks of expandable metal 1140 are held together in an enclosure, cage, etc., as discussed above.

Turning to FIG. 12, illustrated is a cross-sectional view of one embodiment of a downhole tool 1200 (e.g., packer, plug, anchor, etc.) designed, manufactured and/or operated according to one or more alternative embodiments of the disclosure. The downhole tool 1200 of FIG. 12 is similar in many respects to the downhole tool 1000 of FIG. 10. Accordingly, like reference numbers may be used to indicate similar, if not identical, features. The downhole tool 1200 differs from the downhole tool 1000, for the most part, in that the downhole tool 1200 employs a radioisotope generator 1230 thermally coupled with the hot side thermal conductor 870. In at least one embodiment, the radioisotope generator 1230 includes a radioisotope heater unit 1240. In at least one embodiment, the radioisotope heater unit 1240 could include a number of pellets of radioactive material (e.g., pellet of plutonium-238). In at least one embodiment, the radioisotope heater unit 1240 has an output ranging from 0.05 hU/t to 64 hU/t. In yet another embodiment, the radioisotope heater unit 1240 has an output ranging from 2 hU/t to 8 hU/t.

Turning to FIGS. 13 through 18, illustrated is a method for deploying and/or setting a downhole tool 1300 designed, manufactured and/or operated according to one or more embodiments of the disclosure. The downhole tool 1300 of FIGS. 13 through 18 is similar in many respects to the downhole tool 800 of FIGS. 8A and 8B. Accordingly, like reference numbers are used to indicate similar, if not identical, features. With initial reference to FIG. 13, the downhole tool 1300 is in its run-in-hole state, and thus has been positioned at a desired location within the wellbore 895.

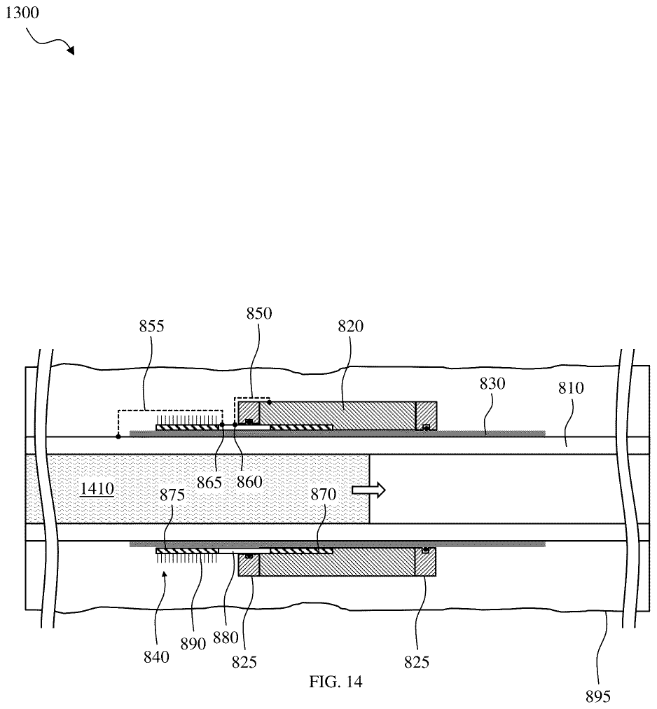

Turning to FIG. 14, illustrated is the downhole tool 1300 of FIG. 13 after wellbore fluid, such as reactive fluid 1410, begins to make its way down the downhole feature 810 (e.g., down the wellbore tubular from uphole in one embodiment).

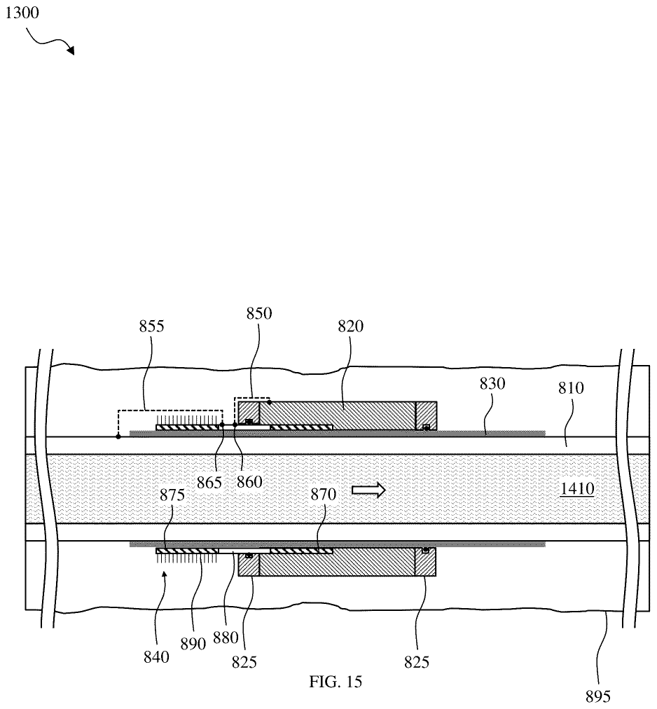

Turning to FIG. 15, illustrated is the downhole tool 1300 of FIG. 14 after wellbore fluid, such as reactive fluid 1410, continues to make its way down the downhole feature 810 (e.g., down the wellbore tubular from uphole in one embodiment).

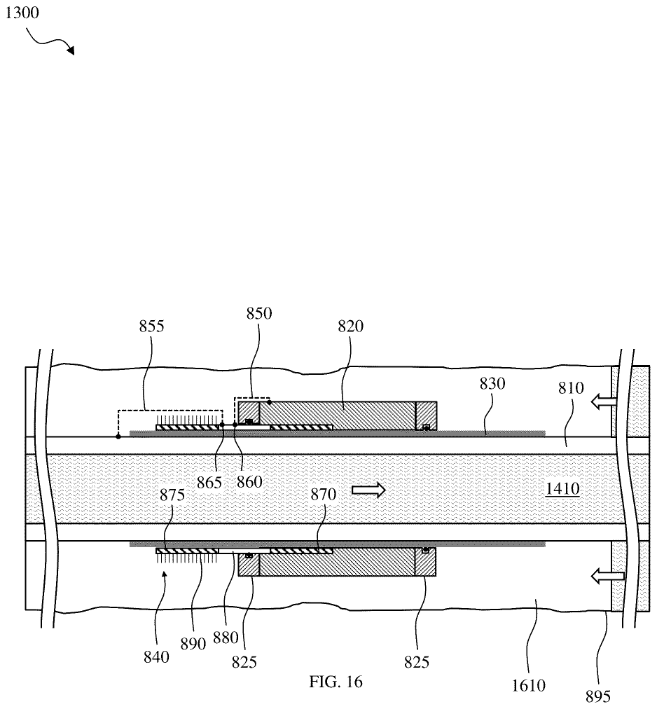

Turning to FIG. 16, illustrated is the downhole tool 1300 of FIG. 15 after wellbore fluid, such as the reactive fluid 1410, begins to make its way up an annulus 1610 between the downhole feature 810 and the wellbore 895 (e.g., up the annulus 1610 from downhole in one embodiment).

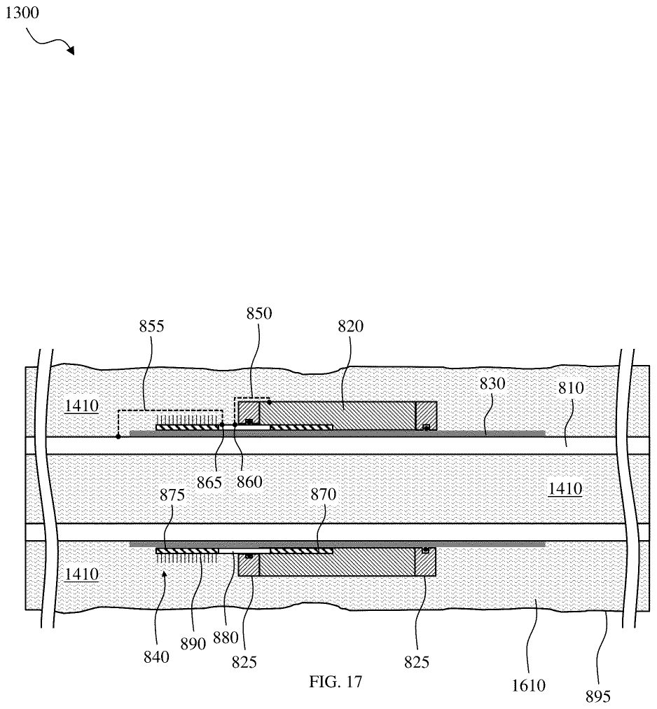

Turning to FIG. 17, illustrated is the downhole tool 1300 of FIG. 16 after wellbore fluid, such as the reactive fluid 1410, fully covers the expandable metal 820 and the thermoelectric generator 840. In the given configuration, the expandable metal 820 (e.g., being in contact with the reactive fluid) starts to undergo hydrolysis. As discussed above, this hydrolysis generates heat through the exothermic electrolytic reaction associated with the hydrolysis of the expandable metal 820. This generated heat, or said another way the temperature differential created across the hot side thermal conductor 870 and the cold side thermal conductor 875 as a result of this generated heat, creates a voltage that is returned to the expandable metal 820 to increase or decrease a rate of reaction of the hydrolysis. In the given embodiment, the expandable metal 820 is coupled to the positive terminal of the thermoelectric generator 840. Accordingly, the returned voltage increases the rate of reaction of the hydrolysis of the expandable metal 820. Nevertheless, the downhole tool 1300 could be wired such that just the opposite holds true (e.g., the returned voltage decreases the rate of reaction of the hydrolysis).

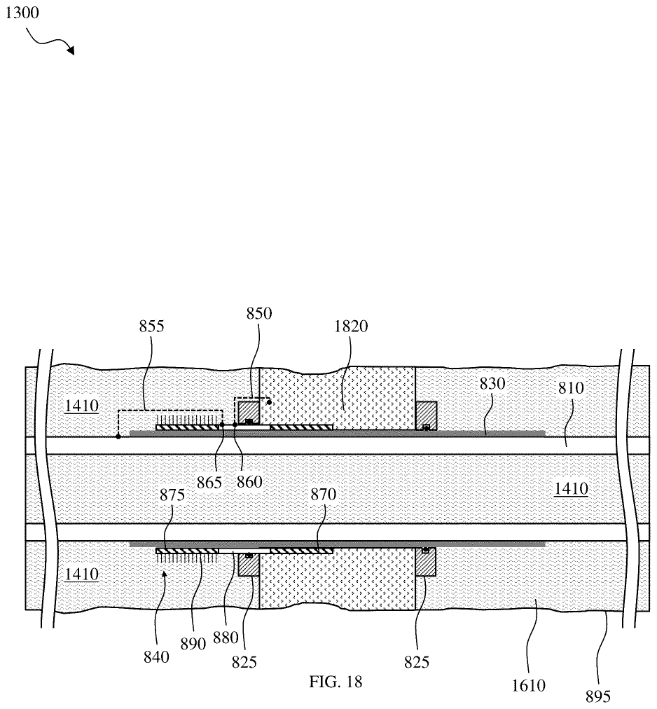

Turning to FIG. 18, illustrated is the downhole tool 1300 of FIG. 17 after the hydrolysis has completed, resulting in expanded metal 1820 (e.g., expanded metal seal and/or anchor). As indicated above, the expanded metal 1820 may include residual unreacted metal in one or more different embodiments.

Turning to FIG. 19, illustrated is a cross-sectional view of one embodiment of a downhole tool 1900 (e.g., packer, plug, anchor, etc.) designed, manufactured and/or operated according to one or more alternative embodiments of the disclosure. The downhole tool 1900 of FIG. 19 is similar in many respects to the downhole tool 800 of FIGS. 8A and 8B. Accordingly, like reference numbers may be used to indicate similar, if not identical, features. The downhole tool 1900 differs from the downhole tool 800, for the most part, in that the downhole tool 1900 employs a flow based generator 1940. The flow based generator 1940 may comprise a variety of different flow based generators that employ the flow of fluid passing thereover or thereby to generate power (e.g., a voltage). In at least one embodiment, the flow based generator 1940 is a hydroelectric generator, for example with an element that spins and/or moves to generate the power (e.g., voltage). In yet another embodiment, the flow based generator 1940 is a piezoelectric impulse generator, for example that employs impulses generated as the fluid moves thereover to generate the power (e.g., voltage).

In the illustrated embodiment of FIG. 19, a first electrode 1950 is coupled between the expandable metal 820 and a first terminal 1960 of the flow based generator 1940. In this embodiment, the first electrode 1950 is configured to provide a voltage to the expandable metal 820 to increase or decrease a rate of reaction of the hydrolysis of the expandable metal 820. Further to this embodiment, a second electrode 1955 is coupled between a downhole feature 1910 and a second terminal 1965 of the flow based generator 1940.

In one or more embodiments, such as that shown in FIG. 19, the downhole feature 1910 is a sacrificial downhole feature, such as a sacrificial expandable metal downhole feature. In this or other similar embodiments, the first electrode 1950 is coupled between the expandable metal 820 and a negative terminal of the flow based generator 1940, thereby causing the expandable metal 820 to function as cathode to decrease the rate of reaction of the hydrolysis of the expandable metal 820, and the second electrode 1955 is coupled between the sacrificial expandable metal downhole feature (e.g., downhole feature 1910) and a positive terminal of the flow based generator 1940, thereby causing the sacrificial expandable metal downhole feature to function as an anode. In this embodiment, the flow based generator would be configured to decrease a rate of reaction of the hydrolysis of the expandable metal 820, and increase a rate of reaction of the hydrolysis of the sacrificial expandable metal downhole feature (e.g., downhole feature 1910).

In at least one embodiment, the flow based generator 1940 encounters the flow of fluid (e.g., reactive fluid) as the downhole tool 1900 is being routed through the wellbore 895. In yet another embodiment, the flow based generator 1940 encounters the flow of fluid (e.g., reactive fluid) as the fluid is routed through an annulus between the wellbore 895 and the wellbore tubular.

Turning to FIG. 20, illustrated is a cross-sectional view of one embodiment of a downhole tool 2000 (e.g., packer, plug, anchor, etc.) designed, manufactured and/or operated according to one or more alternative embodiments of the disclosure. The downhole tool 2000 of FIG. 20 is similar in many respects to the downhole tool 1900 of FIG. 19. Accordingly, like reference numbers may be used to indicate similar, if not identical, features. The downhole tool 2000 differs from the downhole tool 1900, for the most part, in that the downhole tool 2000 employs a thermoelectric generator 2040 (e.g., as its flow based generator). The thermoelectric generator 2040, in this embodiment, includes a hot side thermal conductor 2070 and a cold side thermal conductor 2075 separated by a thermoelectric module 2080, the thermoelectric module 2080 including a plurality of n-type semiconductors and p-type semiconductors connected with each other, as discussed above.

In at least one embodiment, one of the cold side thermal conductor 2075 or hot side thermal conductor 2070 is positioned such that it is configured to be subjected to a flow of fluid while the other of the hot side thermal conductor 2070 or the cold side thermal conductor 2075 is positioned such that it is not configured to be subjected to the flow of fluid, and thereby configured to create a temperature differential between the hot side thermal conductor 2070 and the cold side thermal conductor 2075 to generate the voltage. In at least this one embodiment, the cold side thermal conductor 2075 is positioned such that it is configured to be subjected to the flow of fluid to generate a negative voltage, the first electrode 1950 configured to provide the negative voltage to the expandable metal 820 and provide cathodic protection to the expandable metal 820 and decrease the rate of reaction of the hydrolysis of the expandable metal 820. As discussed above, the downhole feature 1910 may be a sacrificial expandable metal downhole feature. Accordingly, with the above configuration, the hot side thermal conductor 2070 would be coupled to the sacrificial expandable metal downhole feature (e.g., downhole feature 1910), the sacrificial expandable metal downhole feature (e.g., downhole feature 1910) configured to create a second greater temperature differential between the hot side thermal conductor 2070 and the cold side thermal conductor 2075 to generate a second greater negative voltage that further decreases the rate of reaction of the hydrolysis of the expandable metal 820.

Turning to FIG. 21, illustrated is a cross-sectional view of one embodiment of a downhole tool 2100 (e.g., packer, plug, anchor, etc.) designed, manufactured and/or operated according to one or more alternative embodiments of the disclosure. The downhole tool 2100 of FIG. 21 is similar in many respects to the downhole tool 1900 of FIG. 19. Accordingly, like reference numbers may be used to indicate similar, if not identical, features. The downhole tool 2100 differs from the downhole tool 1900 in that the expandable metal 820 is a first expandable metal and the downhole tool 2100 further includes a second expandable metal 2120, wherein the first expandable metal (e.g., expandable metal 820) is configured to protect the second expandable metal 2120 from reactive fluid. In at least one embodiment, the first expandable metal (e.g., expandable metal 820) comprises a first material configured to expand at a first rate in response to hydrolysis and the second expandable metal 2120 comprises a second different material configured to expand at a second rate in response to hydrolysis. For example, the first expandable metal (e.g., expandable metal 820) might comprise a first material configured to expand at a first rate in response to hydrolysis and the second expandable metal 2120 might comprise a second different material configured to expand at a second greater rate in response to hydrolysis.

Turning to FIGS. 22 through 27, illustrated is a method for deploying and/or setting a downhole tool 2200 designed, manufactured and/or operated according to one or more embodiments of the disclosure. The downhole tool 2200 of FIGS. 22 through 27 is similar in many respects to the downhole tool 1900 of FIG. 19. Accordingly, like reference numbers are used to indicate similar, if not identical, features. With initial reference to FIG. 22, the downhole tool 2200 is in its run-in-hole state, and thus has been positioned at a desired location within the wellbore 895.

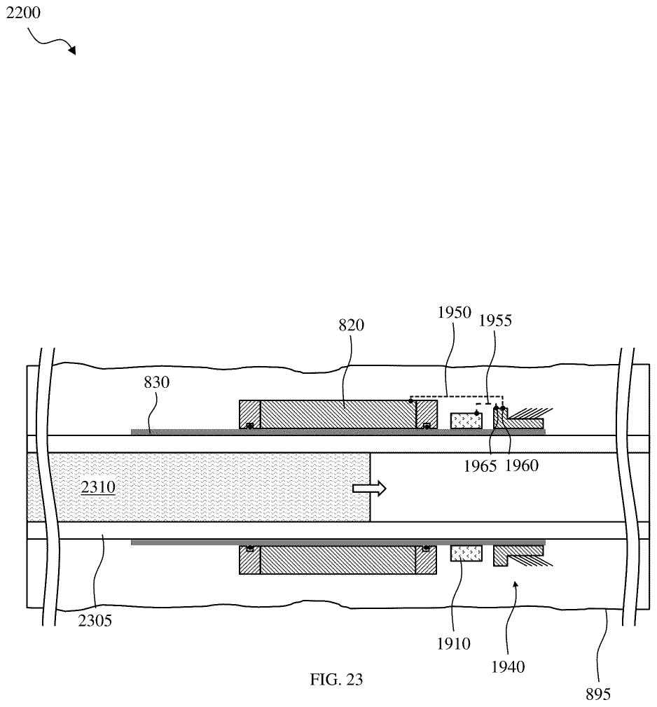

Turning to FIG. 23, illustrated is the downhole tool 2200 of FIG. 22 after wellbore fluid, such as reactive fluid 2310, begins to make its way down the wellbore tubular 2305 (e.g., from uphole in one embodiment).

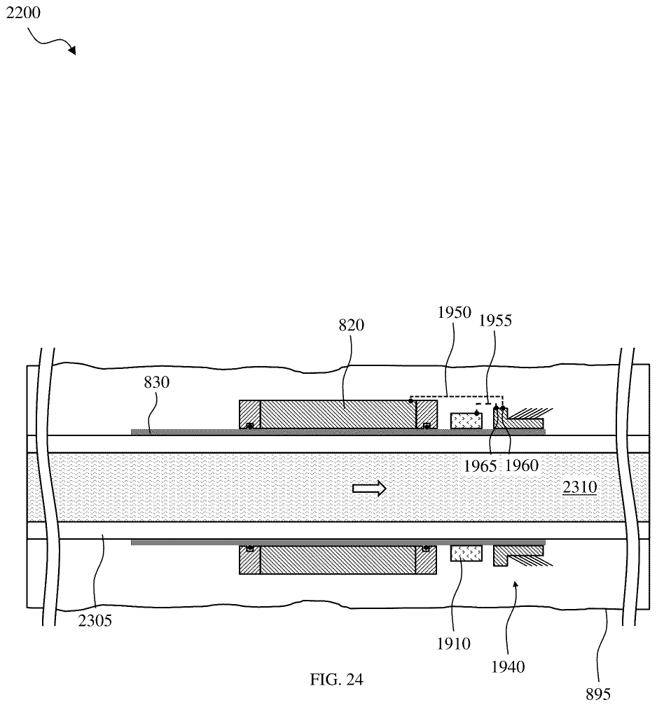

Turning to FIG. 24, illustrated is the downhole tool 2200 of FIG. 23 after wellbore fluid, such as reactive fluid 2310, continues to make its way down the wellbore tubular 2305 (e.g., from uphole in one embodiment).

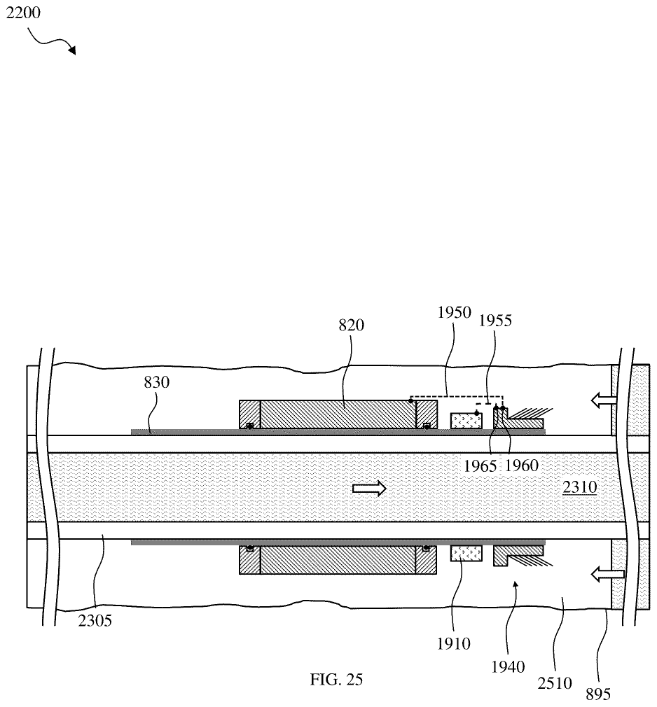

Turning to FIG. 25, illustrated is the downhole tool 2200 of FIG. 24 after wellbore fluid, such as the reactive fluid 2310, begins to make its way up an annulus 2510 between the wellbore tubular 2305 and the wellbore 895 (e.g., from downhole in one embodiment).

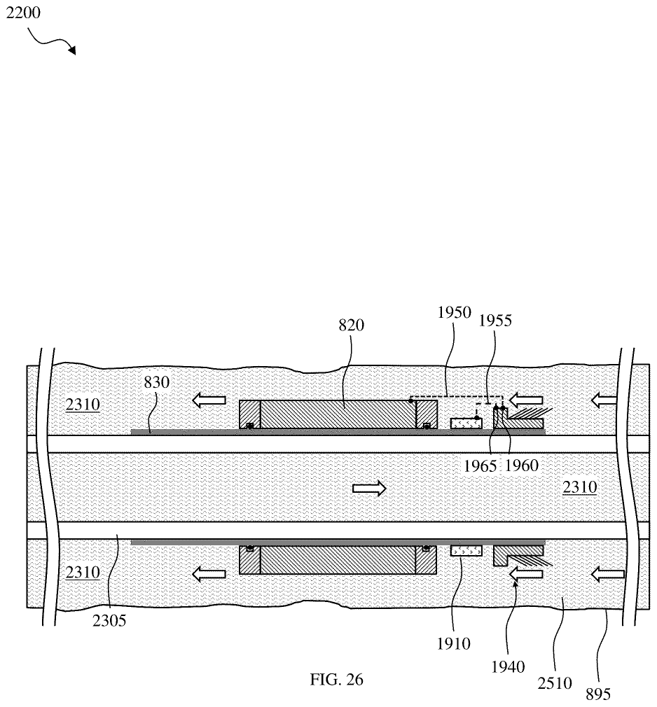

Turning to FIG. 26, illustrated is the downhole tool 2200 of FIG. 25 after wellbore fluid, such as the reactive fluid 2310, is flowing past the flow based generator 1940 and the expandable metal 820. In the given configuration, the flow of the reactive fluid 2310 past the flow based generator 1940 causes the flow based generator 1940 to generate power (e.g., a voltage). In the given embodiment, the expandable metal 820 is coupled to the negative terminal of the flow based generator 1940, and the sacrificial expandable metal downhole feature (e.g., downhole feature 1910) is coupled to the positive terminal of the flow based generator 1940. Accordingly, the negative voltage on the expandable metal 820 decreases the rate of reaction of the hydrolysis of the expandable metal 820, and the positive voltage on the sacrificial expandable metal downhole feature (e.g., downhole feature 1910) increases the rate of reaction of the hydrolysis of the sacrificial expandable metal downhole feature (e.g., downhole feature 1910). Accordingly, the expandable metal 820 is cathodically protected as the fluid reactive 2310 flows past the flow based generator 1940.

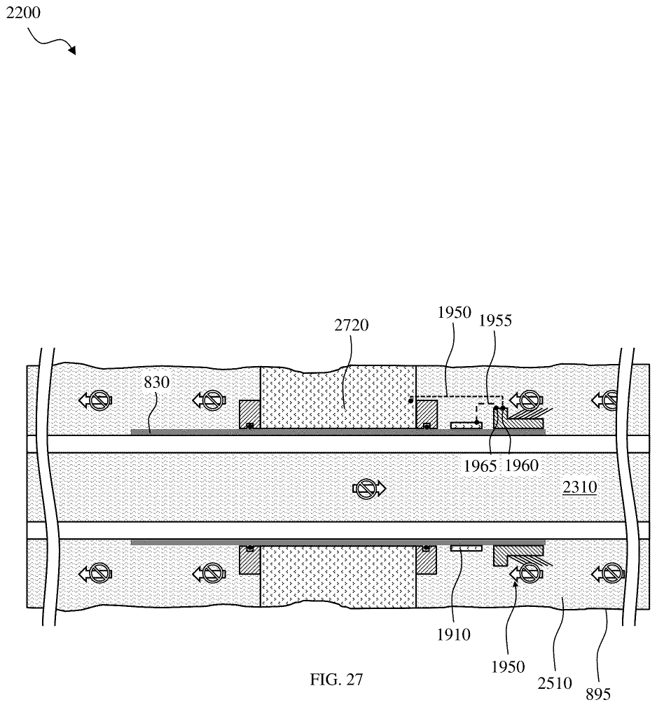

Turning to FIG. 27, illustrated is the downhole tool 2200 of FIG. 26 after the flow of the reactive fluid 2310 has stopped, and thus the flow based generator 1940 is no longer generating power (e.g., a voltage). Accordingly, the flow based generator 1940 no longer cathodically protects the expandable metal 820, and thus the hydrolysis of the expandable metal 820 may begin, ultimately resulting in expanded metal 2720 (e.g., expanded metal seal and/or anchor). As indicated above, the expanded metal 2720 may include residual unreacted metal in one or more different embodiments. Furthermore, the sacrificial expandable metal downhole feature (e.g., downhole feature 1910) may have fully dissolved, or alternatively a portion of the sacrificial expandable metal downhole feature (e.g., downhole feature 1910) may still remain (e.g., as shown).

Turning to FIG. 28, illustrated is a cross-sectional view of one embodiment of a downhole tool 2800 (e.g., packer, plug, anchor, etc.) designed, manufactured and/or operated according to one or more alternative embodiments of the disclosure. The downhole tool 2800 of FIG. 28 is similar in many respects to the downhole tool 800 of FIGS. 8A and 8B. Accordingly, like reference numbers may be used to indicate similar, if not identical, features. The downhole tool 2800 differs from the downhole tool 800, for the most part, in that the downhole tool 2800 employs a radioisotope generator 2840 positioned proximate the expandable metal 820. The radioisotope generator 2840, in at least one embodiment, may comprise a radioisotope heater unit 2845 (e.g., as shown in FIG. 28) or a radioisotope thermoelectric generator (e.g., not shown in FIG. 28) configured to increase or decrease a rate of reaction of the hydrolysis.

As indicated, in the embodiment of FIG. 28, the radioisotope generator 2840 is the radioisotope heater unit 2845 configured to create a temperature spike proximate the expandable metal to increase the rate of reaction. For example, the radioisotope heater unit 2845 could include a number of pellets of radioactive material (e.g., pellet of plutonium-238), each of which would produce heat as they decay. It is the heat from the decay of the radioactive pellets of the radioisotope heater unit 2845 that increases or decreases the rate of reaction of the hydrolysis of the expandable metal 820. Again, in the instant embodiment, the temperature spike increases the rate of reaction of the hydrolysis, and thus speeds the expansion of the expandable metal 820.

In at least one embodiment, the radioisotope heater unit 2845 (e.g., depending on the number of pellets of radioactive material it includes) has an output ranging from 0.05 hU/t to 64 hU/t. In yet another embodiment, the radioisotope heater unit 2845 has an output ranging from 2 hU/t to 8 hU/t. In one example embodiment, one pellet would provide an output of about of 2 hU/t, two pellets would provide an output of about of 4 hU/t, three pellets would provide an output of about of 8 hU/t, four pellets would provide an output of about of 16 hU/t, five pellets would provide an output of about of 32 hU/t, and six pellets would provide an output of about of 64 hU/t.

Turning to FIG. 29, illustrated is a cross-sectional view of one embodiment of a downhole tool 2900 (e.g., packer, plug, anchor, etc.) designed, manufactured and/or operated according to one or more alternative embodiments of the disclosure. The downhole tool 2900 of FIG. 29 is similar in many respects to the downhole tool 2800 of FIG. 28. Accordingly, like reference numbers may be used to indicate similar, if not identical, features. The downhole tool 2900 differs from the downhole tool 2800, for the most part, in that the downhole tool 2900 employs a radioisotope generator 2940 that comprises a radioisotope thermoelectric generator 2945 configured to increase or decrease a rate of reaction of the hydrolysis of the expandable metal 820. The radioisotope thermoelectric generator 2945, in at least one embodiment, is similar to the radioisotope thermoelectric generator 700 of FIG. 7.

In the illustrated embodiment of FIG. 29, the radioisotope thermoelectric generator 2945 includes a first electrode 2950 coupled between the expandable metal 820 and a first terminal 2960 of the radioisotope thermoelectric generator 2945. In this embodiment, the first electrode 2950 is configured to provide a voltage to the expandable metal 820 to increase or decrease the rate of reaction of the hydrolysis of the expandable metal 820. Furthermore, the radioisotope thermoelectric generator 2945 includes a second electrode 2955 coupled between the downhole feature 810 and a second terminal 2965 of the radioisotope thermoelectric generator.

In one or more embodiments, the radioisotope thermoelectric generator 2945 is configured to increase the rate of reaction of the hydrolysis. In this embodiment, the first electrode 2950 is coupled between the expandable metal 820 and a positive terminal of the radioisotope thermoelectric generator 2945, thereby causing the expandable metal 820 to function as an anode to increase the rate of reaction of the hydrolysis of the expandable metal 820, and the second electrode 2955 is coupled between the downhole feature 810 and a negative terminal of the radioisotope thermoelectric generator 2945, thereby causing the downhole feature 810 to function as a cathode.

In yet another embodiment, the radioisotope thermoelectric generator 2945 is configured to decrease the rate of reaction of the hydrolysis. In this embodiment, the first electrode 2950 is coupled between the expandable metal 820 and a negative terminal of the radioisotope thermoelectric generator 2945, thereby causing the expandable metal 820 to function as a cathode to decrease the rate of reaction of the hydrolysis of the expandable metal 820, and the second electrode 2955 is coupled between the downhole feature 810 and a positive terminal of the radioisotope thermoelectric generator 2945, thereby causing the downhole feature 810 to function as an anode.

Turning to FIG. 30, illustrated is a cross-sectional view of one embodiment of a downhole tool 3000 (e.g., packer, plug, anchor, etc.) designed, manufactured and/or operated according to one or more alternative embodiments of the disclosure. The downhole tool 3000 of FIG. 30 is similar in many respects to the downhole tool 2900 of FIG. 29. Accordingly, like reference numbers may be used to indicate similar, if not identical, features. The downhole tool 3000 differs from the downhole tool 2900, for the most part, in that the downhole tool 3000 employs a sacrificial expandable metal downhole feature 3010 for the second electrode 2955 to couple to. Accordingly, in at least this one embodiment, the sacrificial expandable metal downhole feature 3010 functions as the anode.

Turning to FIGS. 31 through 36, illustrated is a method for deploying and/or setting a downhole tool 3100 designed, manufactured and/or operated according to one or more embodiments of the disclosure. The downhole tool 3100 of FIGS. 31 through 36 is similar in many respects to the downhole tool 2800 of FIG. 28. Accordingly, like reference numbers are used to indicate similar, if not identical, features. With initial reference to FIG. 31, the downhole tool 3100 is in its run-in-hole state, and thus has been positioned at a desired location within the wellbore 895.

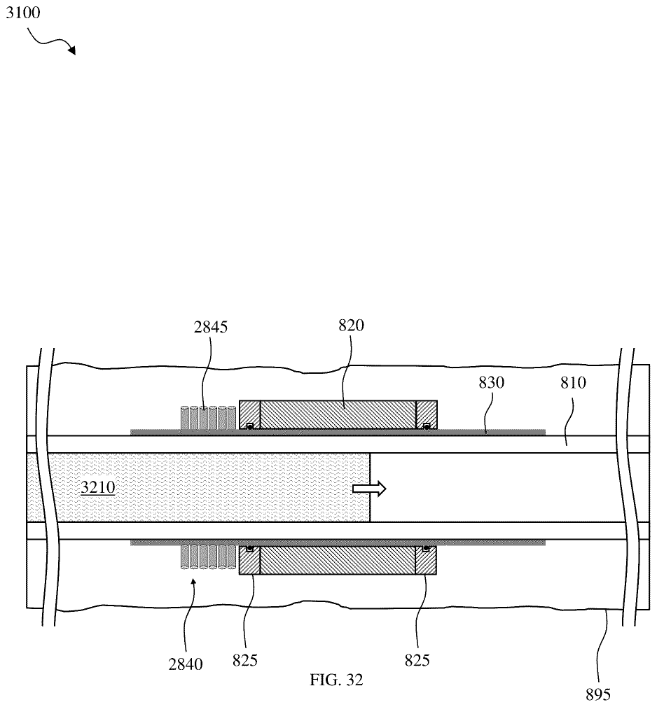

Turning to FIG. 32, illustrated is the downhole tool 3100 of FIG. 31 after wellbore fluid, such as reactive fluid 3210, begins to make its way down the downhole feature 810 (e.g., down the wellbore tubular from uphole in one embodiment).

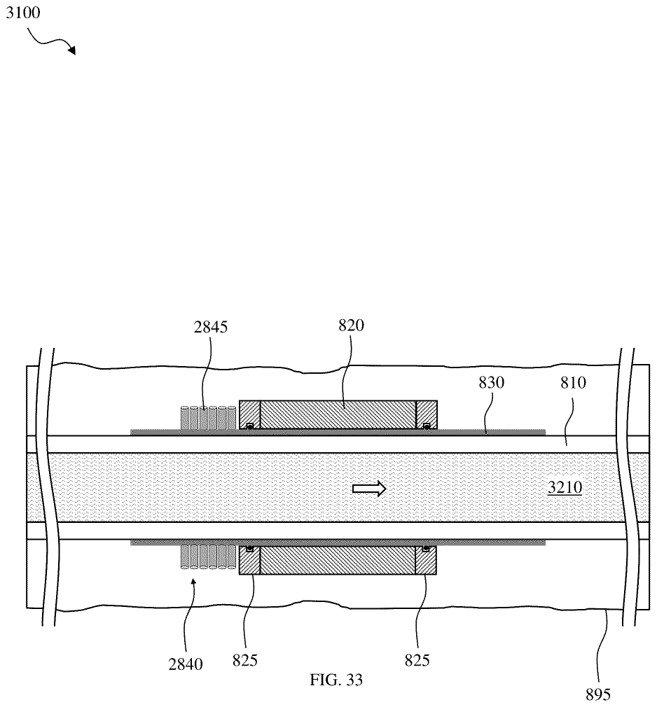

Turning to FIG. 33, illustrated is the downhole tool 3100 of FIG. 32 after wellbore fluid, such as reactive fluid 3210, continues to make its way down the downhole feature 810 (e.g., down the wellbore tubular from uphole in one embodiment).

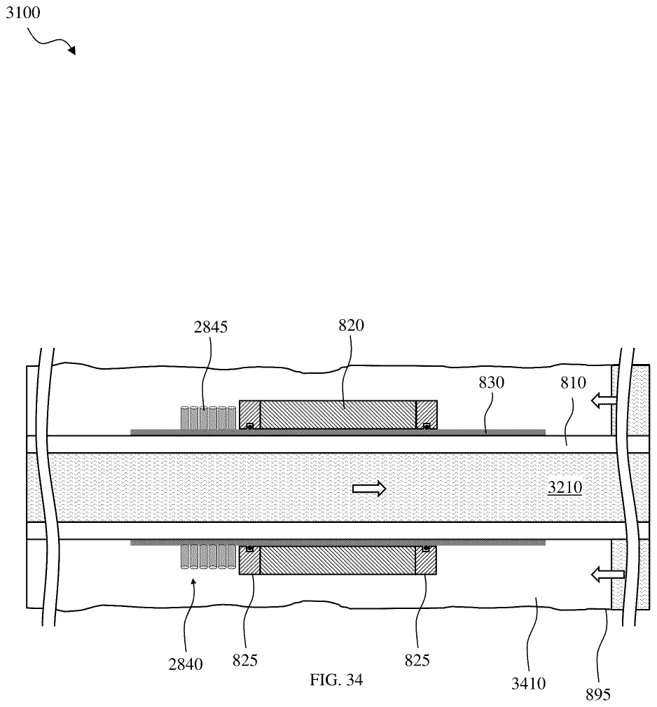

Turning to FIG. 34, illustrated is the downhole tool 3100 of FIG. 33 after wellbore fluid, such as the reactive fluid 3210, begins to make its way up an annulus 3410 between the downhole feature 810 and the wellbore 895 (e.g., up the annulus 3410 from downhole in one embodiment).

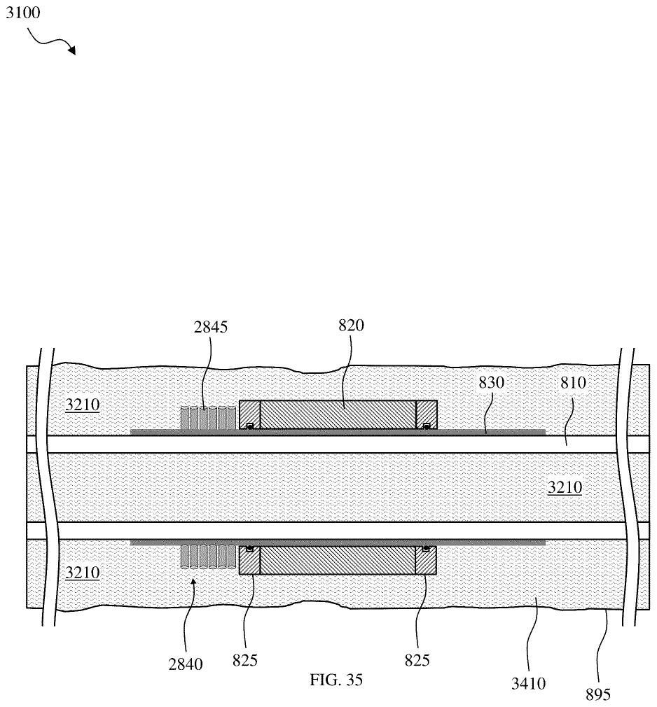

Turning to FIG. 35, illustrated is the downhole tool 3100 of FIG. 34 after wellbore fluid, such as the reactive fluid 3210, fully covers the expandable metal 820 and the radioisotope heater unit 2845. In the given configuration, the expandable metal 820 (e.g., being in contact with the reactive fluid) starts to undergo hydrolysis. At the same time, as indicated above, the radioisotope heater unit 2845 creates a temperature spike proximate the expandable metal 820 to increase the rate of reaction

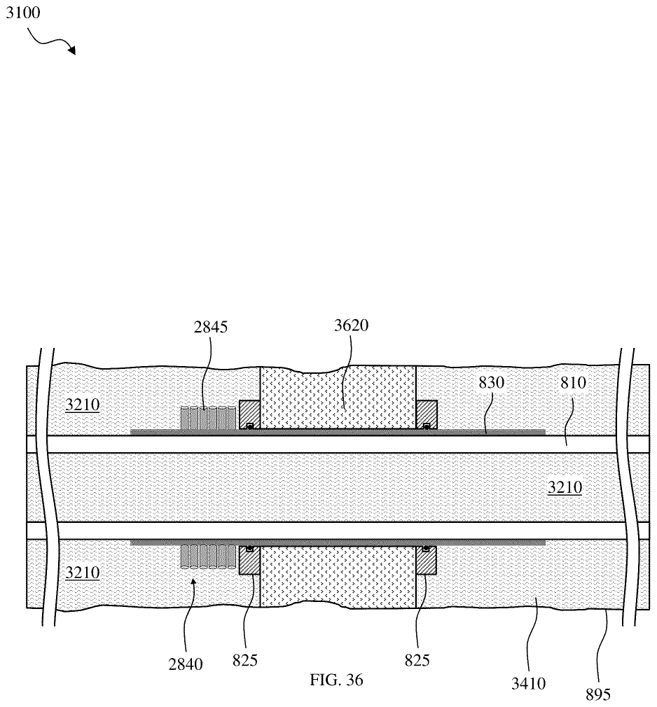

Turning to FIG. 36, illustrated is the downhole tool 3100 of FIG. 35 after the hydrolysis has completed, resulting in expanded metal 3620 (e.g., expanded metal seal and/or anchor). As indicated above, the expanded metal 3620 may include residual unreacted metal in one or more different embodiments.

Turning to FIG. 37, illustrated is a cross-sectional view of one embodiment of a downhole tool 3700 (e.g., packer, plug, anchor, etc.) designed, manufactured and/or operated according to one or more alternative embodiments of the disclosure. The downhole tool 3700, in the illustrated embodiment, includes a combination of the thermoelectric generator 840 (e.g., of FIGS. 8A and 8B), and a flow based generator 1940 (e.g., of FIG. 19). In this disclosed embodiment, the flow based generator 1940 might be configured to decrease the rate of reaction of the hydrolysis of the expandable metal 820 as fluid (e.g., reactive fluid) is flowing over the flow based generator 1940, but once the flow of fluid stops the thermoelectric generator 840 could kick in and increase the rate of reaction of the hydrolysis of the expandable metal 820. Such an embodiment could achieve endless possibilities. It should be noted that any of the different thermoelectric generators, flow based generators, or radioisotope generators comprising the radioisotope heater unit or the radioisotope thermoelectric generator, could be used in conjunction with one another to achieve the endless possibilities discussed above.

Aspects disclosed herein include: [to be completed after approval of the claims by MA]

A. A downhole tool, the downhole tool including: 1) a downhole feature; 2) expandable metal positioned proximate the downhole feature, the expandable metal configured to expand in response to hydrolysis; 3) a first electrode coupled between the expandable metal and a first terminal of a thermoelectric generator, the first electrode configured to provide a voltage to the expandable metal to increase or decrease a rate of reaction of the hydrolysis; and 4) a second electrode coupled between the downhole feature and a second terminal of the thermoelectric generator, wherein the thermoelectric generator includes a hot side thermal conductor and a cold side thermal conductor separated by a thermoelectric module, the thermoelectric module including a plurality of n-type semiconductors and p-type semiconductors connected with each other.

B. A well system, the well system including: 1) a wellbore extending through one or more subterranean formations; and 2) a downhole tool located within the wellbore, the downhole tool including: a) a downhole feature; b) expandable metal positioned proximate the downhole feature, the expandable metal configured to expand in response to hydrolysis; c) a first electrode coupled between the expandable metal and a first terminal of a thermoelectric generator, the first electrode configured to provide a voltage to the expandable metal to increase or decrease a rate of reaction of the hydrolysis; and d) a second electrode coupled between the downhole feature and a second terminal of the thermoelectric generator, wherein the thermoelectric generator includes a hot side thermal conductor and a cold side thermal conductor separated by a thermoelectric module, the thermoelectric module including a plurality of n-type semiconductors and p-type semiconductors connected with each other.

C. A method, the method including: 1) positioning a downhole tool within the wellbore extending through one or more subterranean formations, the downhole tool including: a) a downhole feature; b) expandable metal positioned proximate the downhole feature, the expandable metal configured to expand in response to hydrolysis; c) a first electrode coupled between the expandable metal and a first terminal of a thermoelectric generator, the first electrode configured to provide a voltage to the expandable metal to increase or decrease a rate of reaction of the hydrolysis; and d) a second electrode coupled between the downhole feature and a second terminal of the thermoelectric generator, wherein the thermoelectric generator includes a hot side thermal conductor and a cold side thermal conductor separated by a thermoelectric module, the thermoelectric module including a plurality of n-type semiconductors and p-type semiconductors connected with each other 2) subjecting the expandable metal to reactive fluid; and 3) applying a voltage generated by the thermoelectric generator and supplied via the first electrode to the expandable metal while the expandable metal is being subjected to the reactive fluid.

D. A downhole tool, the downhole tool including: 1) a downhole feature; 2) expandable metal positioned proximate the downhole feature, the expandable metal configured to expand in response to hydrolysis; 3) a first electrode coupled between the expandable metal and a first terminal of a flow based generator, the first electrode configured to provide a voltage to the expandable metal to increase or decrease a rate of reaction of the hydrolysis; and 4) a second electrode coupled between the downhole feature and a second terminal of the flow based generator.

E. A well system, the well system including: 1) a wellbore extending through one or more subterranean formations; and 2) a downhole tool located within the wellbore, the downhole tool including: a) a downhole feature; b) expandable metal positioned proximate the downhole feature, the expandable metal configured to expand in response to hydrolysis; c) a first electrode coupled between the expandable metal and a first terminal of a flow based generator, the first electrode configured to provide a voltage to the expandable metal to increase or decrease a rate of reaction of the hydrolysis; and d) a second electrode coupled between the downhole feature and a second terminal of the flow based generator.

F. A method, the method including: 1) positioning a downhole tool within the wellbore extending through one or more subterranean formations, the downhole tool including: a) a downhole feature; b) expandable metal positioned proximate the downhole feature, the expandable metal configured to expand in response to hydrolysis; c) a first electrode coupled between the expandable metal and a first terminal of a flow based generator, the first electrode configured to provide a voltage to the expandable metal to increase or decrease a rate of reaction of the hydrolysis; and d) a second electrode coupled between the downhole feature and a second terminal of the flow based generator; 2) subjecting the expandable metal to reactive fluid; and 3) applying a voltage generated by the flow based generator and supplied via the first electrode to the expandable metal while the expandable metal is being subjected to the reactive fluid.

G. A downhole tool, the downhole tool including: 1) a downhole feature; 2) expandable metal positioned proximate the downhole feature, the expandable metal configured to expand in response to hydrolysis; and 3) a radioisotope generator positioned proximate the expandable metal, the radioisotope generator comprising a radioisotope heater unit or a radioisotope thermoelectric generator configured to increase or decrease a rate of reaction of the hydrolysis.

H. A well system, the well system including: 1) a wellbore extending through one or more subterranean formations; and 2) a downhole tool located within the wellbore, the downhole tool including: a) a downhole feature; b) expandable metal positioned proximate the downhole feature, the expandable metal configured to expand in response to hydrolysis; and c) a radioisotope generator positioned proximate the expandable metal, the radioisotope generator comprising a radioisotope heater unit or a radioisotope thermoelectric generator configured to increase or decrease a rate of reaction of the hydrolysis.

I. A method, the method including: 1) positioning a downhole tool within the wellbore extending through one or more subterranean formations, the downhole tool including: a) a downhole feature; b) expandable metal positioned proximate the downhole feature, the expandable metal configured to expand in response to hydrolysis; and c) a radioisotope generator positioned proximate the expandable metal, the radioisotope generator comprising a radioisotope heater unit or a radioisotope thermoelectric generator configured to increase or decrease a rate of reaction of the hydrolysis; 2) subjecting the expandable metal to reactive fluid; and 3) applying heat provided by the radioisotope heater unit or a voltage generated by the radioisotope thermoelectric generator to the expandable metal while the expandable metal is being subjected to the reactive fluid.

Aspects A through I may have one or more of the following additional elements in combination: Element 1: wherein the hot side thermal conductor is coupled to the expandable metal, the expandable metal configured to create a temperature differential between the hot side thermal conductor and the cold side thermal conductor during an exothermic electrolytic reaction associated with the hydrolysis to generate the voltage. Element 2: wherein the hot side thermal conductor is placed between the downhole feature and the expandable metal, the expandable metal configured to create a temperature differential between the hot side thermal conductor and the cold side thermal conductor during an exothermic electrolytic reaction associated with the hydrolysis to generate the voltage. Element 3: wherein the hot side thermal conductor is embedded within the expandable metal, the expandable metal configured to create a temperature differential between the hot side thermal conductor and the cold side thermal conductor during an exothermic electrolytic reaction associated with the hydrolysis to generate the voltage. Element 4: further including a fin structure coupled with the cold side thermal conductor, the fin structure configured to amplify a temperature differential between the hot side thermal conductor and the cold side thermal conductor as relatively cooler fluid travels over the fin structure. Element 5: wherein the expandable metal is a first expandable metal configured to generate a first amount of heat during a first exothermic electrolytic reaction associated with the hydrolysis, and further including a second expandable metal configured to generate a second greater amount of heat during a second exothermic electrolytic reaction associated with the hydrolysis, wherein the hot side thermal conductor is positioned more proximate the second expandable metal than the first expandable metal. Element 6: wherein the first expandable metal and the second expandable metal comprise a same material, and further wherein the first expandable metal has a first surface area configured to generate the first amount of heat and the second expandable material has a second greater surface area configured to generate the second greater amount of heat. Element 7: wherein the second expandable metal is a wire of expandable metal or a collection of chunks of expandable metal. Element 8: wherein the first expandable metal comprises a first material configured to generate the first amount of heat and the second expandable metal comprises a second different material configured to generate the second greater amount of heat. Element 9: further including a radioactive isotope heater unit thermally coupled with the hot side thermal conductor. Element 10: wherein the first terminal is a positive terminal and the second terminal is a negative terminal, and further wherein the first electrode is coupled between the expandable metal and the positive terminal of the thermoelectric generator, thereby causing the expandable metal to function as an anode to increase the rate of reaction of the hydrolysis, and the second electrode is coupled between the downhole feature and the negative terminal of the thermoelectric generator, thereby causing the downhole feature to function as a cathode. Element 11: wherein the first terminal is a negative terminal and the second terminal is a positive terminal, and further wherein the first electrode is coupled between the expandable metal and the negative terminal of the thermoelectric generator, thereby causing the expandable metal to function as cathode to decrease the rate of reaction of the hydrolysis, and the second electrode is coupled between the downhole feature and the positive terminal of the thermoelectric generator, thereby causing the downhole feature to function as an anode. Element 12: wherein the first electrode is coupled between the expandable metal and a positive terminal of the thermoelectric generator, thereby causing the expandable metal to function as an anode to increase the rate of reaction of the hydrolysis, and the second electrode is coupled between the downhole feature and a negative terminal of the thermoelectric generator, thereby causing the downhole feature to function as a cathode. Element 13: wherein applying a voltage includes applying a positive voltage. Element 14: wherein the first electrode is coupled between the expandable metal and a negative terminal of the thermoelectric generator, thereby causing the expandable metal to function as cathode to decrease the rate of reaction of the hydrolysis, and the second electrode is coupled between the downhole feature and a positive terminal of the thermoelectric generator, thereby causing the downhole feature to function as an anode. Element 15: wherein applying a voltage includes applying a negative voltage. Element 16: wherein the flow based generator is a hydroelectric generator. Element 17: wherein the flow based generator is a piezoelectric impulse generator. Element 18: wherein the flow based generator is a thermoelectric generator including a hot side thermal conductor and a cold side thermal conductor separated by a thermoelectric module, the thermoelectric module including a plurality of n-type semiconductors and p-type semiconductors connected with each other, and further wherein one of the cold side thermal conductor or hot side thermal conductor is positioned such that it is configured to be subjected to a flow of fluid while the other of the hot side thermal conductor or the cold side thermal conductor is positioned such that it is not configured to be subjected to the flow of fluid, and thereby configured to create a temperature differential between the hot side thermal conductor and the cold side thermal conductor to generate the voltage. Element 19: wherein the cold side thermal conductor is positioned such that it is configured to be subjected to the flow of fluid to generate a negative voltage, the first electrode configured to provide the negative voltage to the expandable metal and provide cathodic protection to the expandable metal and decrease the rate of reaction of the hydrolysis. Element 20: wherein the downhole feature is a sacrificial expandable metal downhole feature, and further wherein the hot side thermal conductor is coupled to the sacrificial expandable metal downhole feature, the sacrificial expandable metal downhole feature configured to create a second greater temperature differential between the hot side thermal conductor and the cold side thermal conductor to generate a second greater negative voltage that further decreases the rate of reaction of the hydrolysis. Element 21: wherein the downhole feature is a sacrificial expandable metal downhole feature, and further wherein the first electrode is coupled between the expandable metal and a negative terminal of the flow based generator, thereby causing the expandable metal to function as cathode to decrease the rate of reaction of the hydrolysis, and the second electrode is coupled between the sacrificial expandable metal downhole feature and a positive terminal of the flow based generator, thereby causing the sacrificial expandable metal downhole feature to function as an anode. Element 22: wherein the expandable metal is a first expandable metal and further including a second expandable metal, wherein the first expandable metal is configured to protect the second expandable metal from reactive fluid. Element 23: wherein the first expandable metal comprises a first material configured to expand at a first rate in response to hydrolysis and the second expandable metal comprises a second different material configured to expand at a second rate in response to hydrolysis. Element 24: wherein the first expandable metal comprises a first material configured to expand at a first rate in response to hydrolysis and the second expandable metal comprises a second different material configured to expand at a second greater rate in response to hydrolysis. Element 25: wherein the first electrode is coupled between the expandable metal and a positive terminal of the flow based generator, thereby causing the expandable metal to function as an anode to increase the rate of reaction of the hydrolysis, and the second electrode is coupled between the downhole feature and a negative terminal of the flow based generator, thereby causing the downhole feature to function as a cathode. Element 26: wherein applying a voltage includes applying a positive voltage. Element 27: wherein the first electrode is coupled between the expandable metal and a negative terminal of the flow based generator, thereby causing the expandable metal to function as cathode to decrease the rate of reaction of the hydrolysis, and the second electrode is coupled between the downhole feature and a positive terminal of the flow based generator, thereby causing the downhole feature to function as an anode. Element 28: wherein applying a voltage includes applying a negative voltage. Element 29: wherein the downhole feature is a sacrificial expandable metal downhole feature. Element 30: wherein the radioisotope generator is the radioisotope heater unit configured to create a temperature spike proximate the expandable metal to increase the rate of reaction. Element 31: wherein the radioisotope heater unit has an output ranging from 0.05 hU/t to 64 hU/t. Element 32: wherein the radioisotope heater unit has an output ranging from 2 hU/t to 8 hU/t. Element 33: wherein the radioisotope generator is the radioisotope thermoelectric generator configured to increase or decrease a rate of reaction of the hydrolysis, and further including: a first electrode coupled between the expandable metal and a first terminal of the radioisotope thermoelectric generator, the first electrode configured to provide a voltage to the expandable metal to increase or decrease the rate of reaction of the hydrolysis; and a second electrode coupled between the downhole feature and a second terminal of the radioisotope thermoelectric generator. Element 34: wherein the radioisotope generator is the radioisotope thermoelectric generator configured to increase the rate of reaction of the hydrolysis. Element 35: wherein the first electrode is coupled between the expandable metal and a positive terminal of the radioisotope thermoelectric generator, thereby causing the expandable metal to function as an anode to increase the rate of reaction of the hydrolysis, and the second electrode is coupled between the downhole feature and a negative terminal of the radioisotope thermoelectric generator, thereby causing the downhole feature to function as a cathode. Element 36: wherein the radioisotope generator is the radioisotope thermoelectric generator configured to decrease the rate of reaction of the hydrolysis. Element 37: wherein the first electrode is coupled between the expandable metal and a negative terminal of the radioisotope thermoelectric generator, thereby causing the expandable metal to function as a cathode to decrease the rate of reaction of the hydrolysis, and the second electrode is coupled between the downhole feature and a positive terminal of the radioisotope thermoelectric generator, thereby causing the downhole feature to function as an anode. Element 38: wherein the downhole feature is a sacrificial expandable metal downhole feature.

Those skilled in the art to which this application relates will appreciate that other and further additions, deletions, substitutions and modifications may be made to the described embodiments.

What is claimed is:

1. A downhole tool, comprising:
a downhole feature;
expandable metal positioned proximate the downhole feature, the expandable metal configured to expand in response to hydrolysis;
a first electrode coupled between the expandable metal and a first terminal of a flow based generator, the first electrode configured to provide a voltage to the expandable metal to increase or decrease a rate of reaction of the hydrolysis; and
a second electrode coupled between the downhole feature and a second terminal of the flow based generator.

2. The downhole tool as recited in claim 1, wherein the flow based generator is a hydroelectric generator.

3. The downhole tool as recited in claim 1, wherein the flow based generator is a piezoelectric impulse generator.

4. The downhole tool as recited in claim 1, wherein the flow based generator is a thermoelectric generator including a hot side thermal conductor and a cold side thermal conductor separated by a thermoelectric module, the thermoelectric module including a plurality of n-type semiconductors and p-type semiconductors connected with each other, and further wherein one of the cold side thermal conductor or hot side thermal conductor is positioned such that it is configured to be subjected to a flow of fluid while the other of the hot side thermal conductor or the cold side thermal conductor is positioned such that it is not configured to be subjected to the flow of fluid, and thereby configured to create a temperature differential between the hot side thermal conductor and the cold side thermal conductor to generate the voltage.

5. The downhole tool as recited in claim 4, wherein the cold side thermal conductor is positioned such that it is configured to be subjected to the flow of fluid to generate a negative voltage, the first electrode configured to provide the negative voltage to the expandable metal and provide cathodic protection to the expandable metal and decrease the rate of reaction of the hydrolysis.

6. The downhole tool as recited in claim 5, wherein the downhole feature is a sacrificial expandable metal downhole feature, and further wherein the hot side thermal conductor is coupled to the sacrificial expandable metal downhole feature, the sacrificial expandable metal downhole feature configured to create a second greater temperature differential between the hot side thermal conductor and the cold side thermal conductor to generate a second greater negative voltage that further decreases the rate of reaction of the hydrolysis.

7. The downhole tool as recited in claim 1, wherein the downhole feature is a sacrificial expandable metal downhole feature, and further wherein the first electrode is coupled between the expandable metal and a negative terminal of the flow based generator, thereby causing the expandable metal to function as cathode to decrease the rate of reaction of the hydrolysis, and the second electrode is coupled between the sacrificial expandable metal downhole feature and a positive terminal of the flow based generator, thereby causing the sacrificial expandable metal downhole feature to function as an anode.

8. The downhole tool as recited in claim 1, wherein the expandable metal is a first expandable metal and further including a second expandable metal, wherein the first expandable metal is configured to protect the second expandable metal from reactive fluid.

9. The downhole tool as recited in claim 8, wherein the first expandable metal comprises a first material configured to expand at a first rate in response to hydrolysis and the second expandable metal comprises a second different material configured to expand at a second rate in response to hydrolysis.

10. The downhole tool as recited in claim 8, wherein the first expandable metal comprises a first material configured to expand at a first rate in response to hydrolysis and the second expandable metal comprises a second different material configured to expand at a second greater rate in response to hydrolysis.

11. A well system, comprising:
a wellbore extending through one or more subterranean formations; and
a downhole tool located within the wellbore, the downhole tool including:
a downhole feature;
expandable metal positioned proximate the downhole feature, the expandable metal configured to expand in response to hydrolysis;
a first electrode coupled between the expandable metal and a first terminal of a flow based generator, the first electrode configured to provide a voltage to the expandable metal to increase or decrease a rate of reaction of the hydrolysis; and
a second electrode coupled between the downhole feature and a second terminal of the flow based generator.

12. The well system as recited in claim 11, wherein the flow based generator is a hydroelectric generator.

13. The well system as recited in claim 11, wherein the flow based generator is a piezoelectric impulse generator.

14. The well system as recited in claim 11, wherein the flow based generator is a thermoelectric generator including a hot side thermal conductor and a cold side thermal conductor separated by a thermoelectric module, the thermoelectric module including a plurality of n-type semiconductors and p-type semiconductors connected with each other, and further wherein one of the cold side thermal conductor or hot side thermal conductor is positioned such that it is configured to be subjected to a flow of fluid while the other of the hot side thermal conductor or the cold side thermal conductor is positioned such that it is not configured to be subjected to the flow of fluid, and thereby configured to create a temperature differential between the hot side thermal conductor and the cold side thermal conductor to generate the voltage.

15. The well system as recited in claim 14, wherein the cold side thermal conductor is positioned such that it is configured to be subjected to the flow of fluid to generate a negative voltage, the first electrode configured to provide the negative voltage to the expandable metal and provide cathodic protection to the expandable metal and decrease the rate of reaction of the hydrolysis.

16. The well system as recited in claim 15, wherein the downhole feature is a sacrificial expandable metal downhole feature, and further wherein the hot side thermal conductor is coupled to the sacrificial expandable metal downhole feature, the sacrificial expandable metal downhole feature configured to create a second greater temperature differential between the hot side thermal conductor and the cold side thermal conductor to generate a second greater negative voltage that further decreases the rate of reaction of the hydrolysis.

17. The well system as recited in claim 11, wherein the downhole feature is a sacrificial expandable metal downhole feature, and further wherein the first electrode is coupled between the expandable metal and a negative terminal of the flow based generator, thereby causing the expandable metal to function as cathode to decrease the rate of reaction of the hydrolysis, and the second electrode is coupled between the sacrificial expandable metal downhole feature and a positive terminal of the flow based generator, thereby causing the sacrificial expandable metal downhole feature to function as an anode.

18. The well system as recited in claim 11, wherein the expandable metal is a first expandable metal and further including a second expandable metal, wherein the first expandable metal is configured to protect the second expandable metal from reactive fluid.

19. The well system as recited in claim 18, wherein the first expandable metal comprises a first material configured to expand at a first rate in response to hydrolysis and the second expandable metal comprises a second different material configured to expand at a second rate in response to hydrolysis.

20. The well system as recited in claim 18, wherein the first expandable metal comprises a first material configured to expand at a first rate in response to hydrolysis and the second expandable metal comprises a second different material configured to expand at a second greater rate in response to hydrolysis.

21. A method, comprising:
positioning a downhole tool within a wellbore extending through one or more subterranean formations, the downhole tool including:
a downhole feature;
expandable metal positioned proximate the downhole feature, the expandable metal configured to expand in response to hydrolysis;
a first electrode coupled between the expandable metal and a first terminal of a flow based generator, the first electrode configured to provide a voltage to the expandable metal to increase or decrease a rate of reaction of the hydrolysis; and
a second electrode coupled between the downhole feature and a second terminal of the flow based generator;
subjecting the expandable metal to reactive fluid; and
applying a voltage generated by the flow based generator and supplied via the first electrode to the expandable metal while the expandable metal is being subjected to the reactive fluid.

22. The method as recited in claim 21, wherein the first electrode is coupled between the expandable metal and a positive terminal of the flow based generator, thereby causing the expandable metal to function as an anode to increase the rate of reaction of the hydrolysis, and the second electrode is coupled between the downhole feature and a negative terminal of the flow based generator, thereby causing the downhole feature to function as a cathode.

23. The method as recited in claim 22, wherein applying a voltage includes applying a positive voltage.

24. The method as recited in claim 21, wherein the first electrode is coupled between the expandable metal and a negative terminal of the flow based generator, thereby causing the expandable metal to function as cathode to decrease the rate of reaction of the hydrolysis, and the second electrode is coupled between the downhole feature and a positive terminal of the flow based generator, thereby causing the downhole feature to function as an anode.

25. The method as recited in claim 24, wherein applying a voltage includes applying a negative voltage.

26. The method as recited in claim 24, wherein the downhole feature is a sacrificial expandable metal downhole feature.
